(19) United States
(12) Patent Application Publication
(10) Pub. No.: US 2026/0328870 A1
(43) Pub. Date: Oct. 22, 2026

(54) METHODS AND APPARATUS FOR DETECTING PORT CONTAMINATION IN PLAYBACK DEVICES

(71) Applicant: Sonos, Inc., Goleta, CA (US)

(72) Inventor: Chadwick J. Souza, Santa Barbara, CA (US)

(21) Appl. No.: 19/113,119

(22) PCT Filed: Sep. 14, 2023
(86) PCT No.: PCT/US2023/074208

§ 371 Date: Mar. 19, 2025

Related U.S. Application Data
(60) Provisional application No. 63/376,487, filed on Sep. 21, 2022.

(51) Int. Cl. G01R 31/69; G01R 31/28; G01R 31/52

(52) U.S. Cl. CPC G01R 31/69; G01R 31/2825; G01R 31/52

(57) ABSTRACT

Methods and playback devices for monitoring for contamination of a combined power/data input port. In one example, a playback device includes an audio output configured to output audio, a rechargeable power source that provides power to the playback device, input circuitry including a multi-pin connector configured to receive both charging power and data, and contamination detection circuitry operably coupled to the multi-pin connector and configured to output a contamination signal indicating a state of contamination of the multi-pin connector. The playback device may further include a tangible, non-transitory computer-readable memory operably connected to a processor and including program instructions that are executable by the processor such that the processor is configured to detect the contamination signal from the contamination detection circuitry, and cause an alert to be provided if the contamination signal indicates that the state of contamination of the multi-pin connector is contaminated.

### CROSS-REFERENCE TO RELATED APPLICATIONS

This application claims priority under 35 U.S.C. § 119(e), Article 4 of the Paris Convention, and PCT Article 8 to co-pending U.S. Provisional Application No. 63/376,487 filed on Sep. 21, 2022 and titled “METHODS AND APPARATUS FOR DETECTING PORT CONTAMINATION IN PLAYBACK DEVICES,” which is hereby incorporated herein by reference in its entirety for all purposes.

### FIELD OF THE DISCLOSURE

The present disclosure is related to consumer goods and, more particularly, to methods, systems, products, features, services, and other elements directed to media playback or some aspect thereof.

### BACKGROUND

Options for accessing and listening to digital audio in an out-loud setting were limited until in 2002, when Sonos, Inc. began development of a new type of playback system. Sonos then filed one of its first patent applications in 2003, entitled “Method for Synchronizing Audio Playback between Multiple Networked Devices,” and began offering its first media playback systems for sale in 2005. The SONOS Wireless Home Sound System enables people to experience music from many sources via one or more networked playback devices. Through a software control application installed on a controller (e.g., smartphone, tablet, computer, voice input device), one can play what she wants in any room having a networked playback device. Media content (e.g., songs, podcasts, video sound) can be streamed to playback devices such that each room with a playback device can play back corresponding different media content. In addition, rooms can be grouped together for synchronous playback of the same media content, and/or the same media content can be heard in all rooms synchronously.

### SUMMARY

Aspects and embodiments are directed to playback devices and methods implemented within playback devices that detect potential contamination of a charging port of a playback device. According to certain examples, a user can be alerted to the potential contamination so that the user can take action to avoid damage to the playback device or its charging cable that could otherwise occur due to the contamination.

According to one embodiment, a playback device comprises one or more processors, an audio output interface operably connected to the one or more processors and configured to output audio, one or more rechargeable power sources configured to provide power to the playback device, input circuitry including a multi-pin connector configured to receive both charging power and data, and contamination detection circuitry operably coupled to the one or more processors and to at least a portion of the multi-pin connector, the contamination detection circuitry configured to output a contamination signal indicating a state of contamination of the multi-pin connector. The playback device may further comprise a tangible, non-transitory computer-readable memory operably connected to the one or more processors and including program instructions that are executable by the one or more processors such that the one or more processors are configured to receive the contamination signal from the contamination detection circuitry, and cause an alert to be provided if the contamination signal indicates that the state of contamination of the multi-pin connector is contaminated.

Embodiments of the playback device may include any one or more of the following features.

In one example, the playback device further comprises recharging circuitry operably connected to the input circuitry and configured to receive and condition the charging power from the input circuitry, and to provide the conditioned charging power to the one or more rechargeable power sources. In another example, the tangible, non-transitory computer-readable memory further includes program instructions that are executable by the one or more processors such that the one or more processors are configured to cause at least a portion of the recharging circuitry to turn off if the contamination signal indicates that the state of contamination of the multi-pin connector is contaminated. In another example, the multi-pin connector comprises one or more data pins configured to receive and transfer at least a portion of the data to the one or more processors, and one or more power pins configured to receive and transfer at least a portion of the charging power to the recharging circuitry.

In certain examples, the contamination detection circuitry may be configured to detect an impedance between at least one of the one or more data pins and at least one of the one or more power pins of the multi-pin connector and to output the contamination signal indicating the state of contamination of the multi-pin connector based on the impedance. In one example, the contamination detection circuitry is configured to output the contamination signal indicating that the state of contamination of the multi-pin connector is contaminated based on the impedance indicating an electrical short between the at least one data pin and the at least one power pin. In another example, the contamination detection circuitry is configured to induce a test current through the at least one data pin and through a known resistance coupled to the at least one power pin, and measure a differential voltage across the known resistance, wherein the tangible, non-transitory computer-readable memory further includes program instructions that are executable by the one or more processors such that the one or more processors are configured to determine a magnitude of the test current based on the measured differential voltage, and to determine the impedance between the at least one data pin and the at least one power pin based on the magnitude of the test current.

In one example, the input circuitry includes a first electrical connection between the at least one data pin and the at least one power pin, the first electrical connection having a known first impedance value, and the contamination detection circuitry is configured to detect a second impedance value between the at least one data pin and the at least one power pin, and output the contamination signal indicating the state of contamination of the multi-pin connector based on the second impedance value. In another example, the contamination detection circuitry includes a test resistance coupled to the at least one data pin and to the at least one power pin, and a differential amplifier configured to measure a voltage across the test resistance, wherein the contamination detection circuitry is configured to output the contamination signal based on the measured voltage across the test resistance. In another example, wherein the tangible, non-transitory computer-readable memory further includes program instructions that are executable by the one or more processors such that the one or more processors are configured to receive the second impedance value, compare the second impedance value to the known first impedance value to determine an impedance change value, determine if the contamination signal comprises an indication of an impedance event based on the impedance change value, and cause the playback device to provide the alert if the one or more processors determine the indication of the impedance event. The indication of the impedance event may include an indication that there is an electrical short between the at least one data pin and the at least one power pin of the multi-pin connector, for example.

In another example, the contamination detection circuitry comprises at least one test resistor configured to measure the second impedance value, and at least one operational amplifier operably connected to the at least one test resistor and configured to output the contamination signal.

In one example, wherein the tangible, non-transitory computer-readable memory further includes program instructions that are executable by the one or more processors such that the one or more processors are configured to determine if an external cable is connected to the input circuitry, and if the external cable is not connected to the input circuitry, process the contamination signal according to a first processing schedule. The tangible, non-transitory computer-readable memory may further include program instructions that are executable by the one or more processors such that the one or more processors are configured to process the contamination signal according to a second processing schedule if the external cable is connected to the input circuitry, wherein the second processing schedule comprises processing the contamination signal more frequently than the first processing schedule.

In one example, the multi-pin connector is a universal serial bus (USB) type-C connector.

In one example, the tangible, non-transitory computer-readable memory further includes program instructions that are executable by the one or more processors such that the one or more processors are configured to receive a first audio stream via the input circuitry, and cause the playback device to play back audio content based on the first audio stream via the audio output interface. In another example, the playback device comprises one or more wireless communication interfaces, and the tangible, non-transitory computer-readable memory further includes program instructions that are executable by the one or more processors such that the one or more processors are configured to generate a second audio stream based on the first audio stream, and transmit the second audio stream to at least one other playback device via the one or more wireless communication interfaces. In another example, the program instructions that are executable by the one or more processors such that the one or more processors are configured to cause the playback device to play back the second audio content comprise program instructions that are executable by the one or more processors are configured to cause the playback device to play back the second audio content in synchrony with the at least one other playback device.

In another example, the playback device further comprises one or more wireless communication interfaces, and the program instructions that are executable by the one or more processors such that the one or more processors are configured to cause an alert to be provided if the contamination signal indicates that the state of contamination of the multi-pin connector is contaminated comprise program instructions that are executable by the one or more processors are configured to cause the playback device to transmit an indication that the multi-pin connector is contaminated to at least one external device via the one or more wireless communication interfaces.

According to another embodiment, a playback device assembly comprises a playback device including input circuitry having a multi-pin connector configured to receive both charging power and data, and a multi-function cable configured to be connected to the multi-pin connector. The playback device of the playback device assembly may further include one or more processors, an audio output interface operably connected to the one or more processors and configured to output audio, one or more rechargeable power sources configured to provide power to the playback device, and contamination detection circuitry operably coupled to the one or more processors and to at least a portion of the multi-pin connector, the contamination detection circuitry configured to output a contamination signal indicating a state of contamination of the multi-pin connector. The playback device may further include a tangible, non-transitory computer-readable memory operably connected to the one or more processors and including program instructions that are executable by the one or more processors such that the one or more processors are configured to receive the contamination signal from the contamination detection circuitry, and cause an alert to be provided if the contamination signal indicates that the state of contamination of the multi-pin connector is contaminated.

The playback device assembly may include any one or more of the following features, and any one or more of the features of the playback devices discussed above.

In one example, the multi-pin connector is a universal serial bus (USB) type-C connector, and the multi-function cable includes a mating USB type-C connector.

In one example, the input circuitry is configured to receive the charging power and the data via the multi-function cable.

In another example, the multi-pin connector includes one or more data pins configured to receive and transfer at least a portion of the data to the one or more processors, and one or more power pins configured to receive and transfer at least a portion of the charging power to the one or more rechargeable power sources, and the contamination detection circuitry is configured to detect an impedance value between at least one data pin of the one or more data pins and at least one power pin of the one or more power pins and to output the contamination signal indicating the impedance value. The tangible, non-transitory computer-readable memory may further include program instructions are executable by the one or more processors such that the one or more processors are configured to compare the impedance value indicated by the contamination signal to a known expected impedance value to determine an impedance change value, and to cause the alert to be provided if the impedance change value indicates that the state of contamination of the multi-pin connector is contaminated.

In another example, the multi-function cable includes a resettable fuse that is configured to have an impedance that increases with temperature.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one example are discussed below with reference to the accompanying figures, which are not intended to be drawn to scale. The figures are included to provide an illustration and a further understanding of the various aspects and are incorporated in and constitute a part of this disclosure. However, the figures are not intended as a definition of the limits of any particular example. The figures, together with the remainder of this disclosure, serve to explain principles and operations of the described and claimed aspects. In the figures, the same or similar components that are illustrated are represented by a like reference numeral. For purposes of clarity, every component may not be labeled in every figure. In the figures:

FIG. 1A is a partial cutaway view of an environment having a media playback system configured in accordance with aspects of the disclosed technology;

FIG. 1B is a schematic diagram of the media playback system of FIG. 1A and one or more networks;

FIG. 1C is a block diagram of a playback device;

FIG. 1D is a block diagram of a playback device;

FIG. 1E is a block diagram of a bonded playback device;

FIG. 1F is a block diagram of a network microphone device;

FIG. 1G is a block diagram of a playback device;

FIG. 1H is a partial schematic diagram of a control device;

FIG. 2 is a block diagram of one example of a playback device incorporating circuitry in accordance with aspects of the disclosed technology;

FIG. 3 is a diagram of one example of a multi-pin connector that can be used in embodiments of the playback device of FIG. 2, according to aspects disclosed herein;

FIG. 4 is a block diagram of one example of circuitry that can be included in a playback device to perform port contamination detection according to aspects disclosed herein;

FIG. 5 is a partial circuit diagram of one example of an implementation of a portion of the circuitry of FIG. 4; and

FIG. 6 is a partial circuit diagram of another example of an implementation of a portion of the circuitry of FIG. 4.

### DETAILED DESCRIPTION

### I. Overview

Various embodiments of audio playback devices described herein can be configured to receive both audio data and line power via a powered communication port, such as a universal serial bus (USB) port, for example. With the development of portable playback devices having a powered communication port, such as a USB-C port, for example, several disadvantages to the physical design of USB receptacles, in particular USB-C receptacles, have been discovered. For example, USB-C receptacles are prone to contamination that can cause an electrical short to occur between pins in the USB receptacle. For example, a USB port may not have fully dried from prior contact with water, and the remaining moisture can cause a short between certain pins when a user plugs in a USB charging cable to charge the playback device. In another example, if the playback device has been dropped in a pool, or the USB port has otherwise come into contact with chemically treated water, the water may leave a residue in the USB port after the port has dried (e.g., from chlorine or other chemicals in the water), the residue being sufficiently conductive to cause an electrical short between pins when the charging cable is plugged in. Such electrical shorts can result in disruption of communication with the playback device and possible damage to the playback device. For example, if power is supplied, via the charging cable, to the USB port on the playback device where at least one of the power pins is electrically shorted to another pin, such as a data pin, for example, the short can cause overheating, which may melt part of the USB receptacle housing and/or part of the charging cable attached to the USB port.

Accordingly, aspects and embodiments are directed to methods and apparatus to reliably detect contamination in the USB port and, upon detection of contamination in the USB port, stop USB charging (e.g., to avoid melting the USB cable or otherwise posing a safety risk to the user) and notify the user so that appropriate action can be taken (e.g., clean out the USB receptacle, use a different charging cable, etc.).

As discussed in more detail below, according to certain embodiments, contamination of the USB port can be detected by monitoring an impedance between selected pins and detecting changes in the impedance that indicate a possible electrical short between the pins. In some examples, it may be desirable to monitor the impedance between certain power pins and data pins; however, this can present technical challenges because the voltage across the data pins may be rapidly changing as data is communicated over those pins. Accordingly, as discussed further below, in order to monitor for port contamination without disrupting communication over the data pins, certain implementations use circuitry configured to induce a test current through the data pins and through a known impedance to a reference voltage, and to measure a differential voltage across the known resistance (to account for the voltage fluctuations on the data pins during operation). Based on these differential voltage measurements, the magnitude of the test current can be determined, which provides an indication of the impedance between the data pins and the reference voltage. Playback devices can be configured with this contamination detection circuitry and operated to monitor for potential contamination and signal an alert if contamination is detected.

According to certain embodiments, a playback device comprises one or more processors, an audio output interface operably connected to the one or more processors and configured to output audio, one or more rechargeable power sources configured to provide power to the playback device, input circuitry including a multi-pin connector configured to receive both charging power and data, and contamination detection circuitry operably coupled to the one or more processors and to at least a portion of the multi-pin connector. The contamination detection circuitry can be configured to output a contamination signal indicating a state of contamination of the multi-pin connector. The playback device can further comprise a tangible, non-transitory computer-readable memory operably connected to the one or more processors and including program instructions that are executable by the one or more processors such that the one or more processors are configured to receive the contamination signal from the contamination detection circuitry, and cause an alert to be provided if the contamination signal indicates that the state of contamination of the multi-pin connector is contaminated.

While some examples described herein may refer to functions performed by given actors such as “users,” “listeners,” and/or other entities, it should be understood that this is for purposes of explanation only. The claims should not be interpreted to require action by any such example actor unless explicitly required by the language of the claims themselves.

### II. Suitable Operating Environment

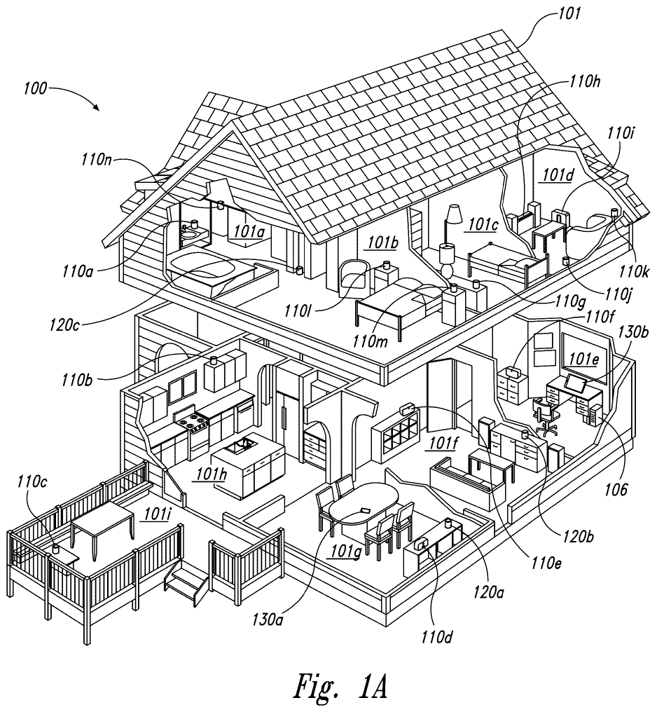

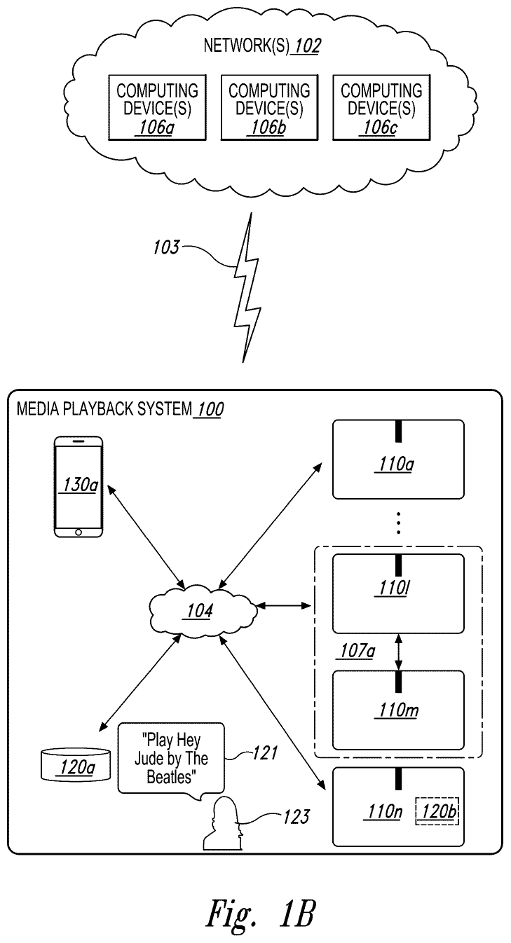

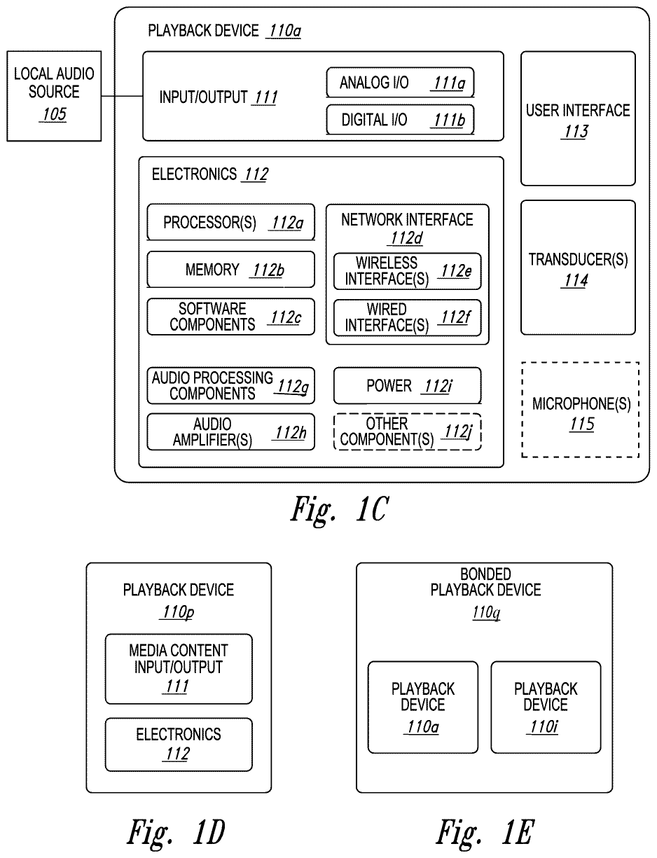

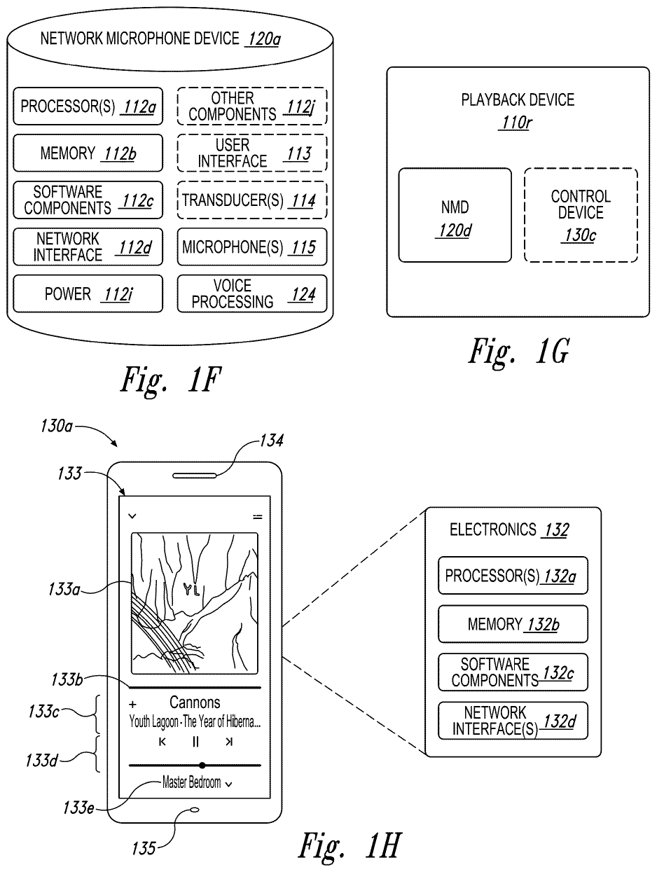

FIG. 1A is a partial cutaway view of a media playback system 100 distributed in an environment 101 (e.g., a house). The media playback system 100 comprises one or more playback devices 110 (identified individually as playback devices 110a-n), one or more network microphone devices 120 (“NMDs”) (identified individually as NMDs 120a-c), and one or more control devices 130 (identified individually as control devices 130a and 130b).

As used herein the term “playback device” can generally refer to a network device configured to receive, process, and output data of a media playback system. For example, a playback device can be a network device that receives and processes audio content. In some embodiments, a playback device includes one or more transducers or speakers powered by one or more amplifiers. In other embodiments, however, a playback device includes one of (or neither of) the speaker and the amplifier. For instance, a playback device can comprise one or more amplifiers configured to drive one or more speakers external to the playback device via a corresponding wire or cable.

Moreover, as used herein the term “NMD” (i.e., a “network microphone device”) can generally refer to a network device that is configured for audio detection. In some embodiments, an NMD is a stand-alone device configured primarily for audio detection. In other embodiments, an NMD is incorporated into a playback device (or vice versa).

The term “control device” can generally refer to a network device configured to perform functions relevant to facilitating user access, control, and/or configuration of the media playback system 100.

Each of the playback devices 110 is configured to receive audio signals or data from one or more media sources (e.g., one or more remote servers, one or more local devices, etc.) and play back the received audio signals or data as sound. The one or more NMDs 120 are configured to receive spoken word commands, and the one or more control devices 130 are configured to receive user input. In response to the received spoken word commands and/or user input, the media playback system 100 can play back audio via one or more of the playback devices 110. In certain embodiments, the playback devices 110 are configured to commence playback of media content in response to a trigger. For instance, one or more of the playback devices 110 can be configured to play back a morning playlist upon detection of an associated trigger condition (e.g., presence of a user in a kitchen, detection of a coffee machine operation, etc.). In some embodiments, for example, the media playback system 100 is configured to play back audio from a first playback device (e.g., the playback device 110a) in synchrony with a second playback device (e.g., the playback device 110b). Interactions between the playback devices 110, NMDs 120, and/or control devices 130 of the media playback system 100 configured in accordance with the various embodiments of the disclosure are described in greater detail below with respect to FIGS. 1B-1H.

In the illustrated embodiment of FIG. 1A, the environment 101 comprises a household having several rooms, spaces, and/or playback zones, including (clockwise from upper left) a master bathroom 101a, a master bedroom 101b, a second bedroom 101c, a family room or den 101d, an office 101e, a living room 101f, a dining room 101g, a kitchen 101h, and an outdoor patio 101i. While certain embodiments and examples are described below in the context of a home environment, the technologies described herein may be implemented in other types of environments. In some embodiments, for example, the media playback system 100 can be implemented in one or more commercial settings (e.g., a restaurant, mall, airport, hotel, a retail or other store), one or more vehicles (e.g., a sports utility vehicle, bus, car, a ship, a boat, an airplane, etc.), multiple environments (e.g., a combination of home and vehicle environments), and/or another suitable environment where multi-zone audio may be desirable.

The media playback system 100 can comprise one or more playback zones, some of which may correspond to the rooms in the environment 101. The media playback system 100 can be established with one or more playback zones, after which additional zones may be added, or removed, to form, for example, the configuration shown in FIG. 1A. Each zone may be given a name according to a different room or space such as the office 101e, master bathroom 101a, master bedroom 101b, the second bedroom 101c, kitchen 101h, dining room 101g, living room 101f, and/or the balcony 101i. In some aspects, a single playback zone may include multiple rooms or spaces. In certain aspects, a single room or space may include multiple playback zones.

In the illustrated embodiment of FIG. 1A, the second bedroom 101c, the office 101e, the living room 101f, the dining room 101g, the kitchen 101h, and the outdoor patio 101i each include one playback device 110, and the master bedroom 101b, the master bathroom 101a, and the den 101d include a plurality of playback devices 110. In the master bedroom 101b, the playback devices 1101 and 110m may be configured, for example, to play back audio content in synchrony as individual ones of playback devices 110, as a bonded playback zone, as a consolidated playback device, and/or any combination thereof. Similarly, in the den 101d, the playback devices 110h-k can be configured, for instance, to play back audio content in synchrony as individual ones of playback devices 110, as one or more bonded playback devices, and/or as one or more consolidated playback devices. Additional details regarding bonded and consolidated playback devices are described below with respect to FIGS. 1B and 1E.

In some aspects, one or more of the playback zones in the environment 101 may each be playing different audio content. For instance, a user may be grilling on the patio 101i and listening to hip hop music being played by the playback device 110c while another user is preparing food in the kitchen 101h and listening to classical music played by the playback device 110b. In another example, a playback zone may play the same audio content in synchrony with another playback zone. For instance, the user may be in the office 101e listening to the playback device 110f playing back the same hip hop music being played back by playback device 110c on the patio 101i. In some aspects, the playback devices 110c and 110f play back the hip hop music in synchrony such that the user perceives that the audio content is being played seamlessly (or at least substantially seamlessly) while moving between different playback zones. Additional details regarding audio playback synchronization among playback devices and/or zones can be found, for example, in U.S. Pat. No. 8,234,395 entitled, “System and method for synchronizing operations among a plurality of independently clocked digital data processing devices,” which is incorporated herein by reference in its entirety.

a. Suitable Media Playback System

FIG. 1B is a schematic diagram of the media playback system 100 and a cloud network 102. For ease of illustration, certain devices of the media playback system 100 and the cloud network 102 are omitted from FIG. 1B. One or more communication links 103 (referred to hereinafter as “the links 103”) communicatively couple the media playback system 100 and the cloud network 102.

The links 103 can comprise, for example, one or more wired networks, one or more wireless networks, one or more wide area networks (WAN), one or more local area networks (LAN), one or more personal area networks (PAN), one or more telecommunication networks (e.g., one or more Global System for Mobiles (GSM) networks, Code Division Multiple Access (CDMA) networks, Long-Term Evolution (LTE) networks, 5G communication network networks, and/or other suitable data transmission protocol networks), etc. The cloud network 102 is configured to deliver media content (e.g., audio content, video content, photographs, social media content, etc.) to the media playback system 100 in response to a request transmitted from the media playback system 100 via the links 103. In some embodiments, the cloud network 102 is further configured to receive data (e.g., voice input data) from the media playback system 100 and correspondingly transmit commands and/or media content to the media playback system 100.

The cloud network 102 comprises computing devices 106 (identified separately as a first computing device 106a, a second computing device 106b, and a third computing device 106c). The computing devices 106 can comprise individual computers or servers, such as, for example, a media streaming service server storing audio and/or other media content, a voice service server, a social media server, a media playback system control server, etc. In some embodiments, one or more of the computing devices 106 comprise modules of a single computer or server. In certain embodiments, one or more of the computing devices 106 comprise one or more modules, computers, and/or servers. Moreover, while the cloud network 102 is described above in the context of a single cloud network, in some embodiments the cloud network 102 comprises a plurality of cloud networks comprising communicatively coupled computing devices. Furthermore, while the cloud network 102 is shown in FIG. 1B as having three of the computing devices 106, in some embodiments, the cloud network 102 comprises fewer (or more than) three computing devices 106.

The media playback system 100 is configured to receive media content from the networks 102 via the links 103. The received media content can comprise, for example, a Uniform Resource Identifier (URI) and/or a Uniform Resource Locator (URL). For instance, in some examples, the media playback system 100 can stream, download, or otherwise obtain data from a URI or a URL corresponding to the received media content. A network 104 communicatively couples the links 103 and at least a portion of the devices (e.g., one or more of the playback devices 110, NMDs 120, and/or control devices 130) of the media playback system 100. The network 104 can include, for example, a wireless network (e.g., a WIFI network, a BLUETOOTH network, a Z-WAVE network, a ZIGBEE network, and/or other suitable wireless communication protocol network) and/or a wired network (e.g., a network comprising Ethernet, Universal Serial Bus (USB), and/or another suitable wired communication). As those of ordinary skill in the art will appreciate, as used herein, “WIFI” can refer to several different communication protocols including, for example, Institute of Electrical and Electronics Engineers (IEEE) 802.11a, 802.11b, 802.11g, 802.11n, 802.11ac, 802.11ac, 802.11ad, 802.11af, 802.11ah, 802.11ai, 802.11aj, 802.11aq, 802.11ax, 802.11ay, 802.15, etc. transmitted at 2.4 Gigahertz (GHz), 5 GHZ, and/or another suitable frequency.

In some embodiments, the network 104 comprises a dedicated communication network that the media playback system 100 uses to transmit messages between individual devices and/or to transmit media content to and from media content sources (e.g., one or more of the computing devices 106). In certain embodiments, the network 104 is configured to be accessible only to devices in the media playback system 100, thereby reducing interference and competition with other household devices. In other embodiments, however, the network 104 comprises an existing household or commercial facility communication network (e.g., a household or commercial facility WIFI network). In some embodiments, the links 103 and the network 104 comprise one or more of the same networks. In some aspects, for example, the links 103 and the network 104 comprise a telecommunication network (e.g., an LTE network, a 5G network, etc.). Moreover, in some embodiments, the media playback system 100 is implemented without the network 104, and devices comprising the media playback system 100 can communicate with each other, for example, via one or more direct connections, PANs, telecommunication networks, and/or other suitable communication links. The network 104 may be referred to herein as a “local communication network” to differentiate the network 104 from the cloud network 102 that couples the media playback system 100 to remote devices, such as cloud servers that host cloud services.

In some embodiments, audio content sources may be regularly added or removed from the media playback system 100. In some embodiments, for example, the media playback system 100 performs an indexing of media items when one or more media content sources are updated, added to, and/or removed from the media playback system 100. The media playback system 100 can scan identifiable media items in some or all folders and/or directories accessible to the playback devices 110, and generate or update a media content database comprising metadata (e.g., title, artist, album, track length, etc.) and other associated information (e.g., URIs, URLs, etc.) for each identifiable media item found. In some embodiments, for example, the media content database is stored on one or more of the playback devices 110, network microphone devices 120, and/or control devices 130.

In the illustrated embodiment of FIG. 1B, the playback devices 1101 and 110m comprise a group 107a. The playback devices 1101 and 110m can be positioned in different rooms and be grouped together in the group 107a on a temporary or permanent basis based on user input received at the control device 130a and/or another control device 130 in the media playback system 100. When arranged in the group 107a, the playback devices 1101 and 110m can be configured to play back the same or similar audio content in synchrony from one or more audio content sources. In certain embodiments, for example, the group 107a comprises a bonded zone in which the playback devices 1101 and 110m comprise left audio and right audio channels, respectively, of multi-channel audio content, thereby producing or enhancing a stereo effect of the audio content. In some embodiments, the group 107a includes additional playback devices 110. In other embodiments, however, the media playback system 100 omits the group 107a and/or other grouped arrangements of the playback devices 110.

The media playback system 100 includes the NMDs 120a and 120b, each comprising one or more microphones configured to receive voice utterances from a user. In the illustrated embodiment of FIG. 1B, the NMD 120a is a standalone device and the NMD 120b is integrated into the playback device 110n. The NMD 120a, for example, is configured to receive voice input 121 from a user 123. In some embodiments, the NMD 120a transmits data associated with the received voice input 121 to a voice assistant service (VAS) configured to (i) process the received voice input data and (ii) facilitate one or more operations on behalf of the media playback system 100.

In some aspects, for example, the computing device 106c comprises one or more modules and/or servers of a VAS (e.g., a VAS operated by one or more of SONOS, AMAZON, GOOGLE, APPLE, MICROSOFT, etc.). The computing device 106c can receive the voice input data from the NMD 120a via the network 104 and the links 103.

In response to receiving the voice input data, the computing device 106c processes the voice input data (i.e., “Play Hey Jude by The Beatles”), and determines that the processed voice input includes a command to play a song (e.g., “Hey Jude”). In some embodiments, after processing the voice input, the computing device 106c accordingly transmits commands to the media playback system 100 to play back “Hey Jude” by the Beatles from a suitable media service (e.g., via one or more of the computing devices 106) on one or more of the playback devices 110. In other embodiments, the computing device 106c may be configured to interface with media services on behalf of the media playback system 100. In such embodiments, after processing the voice input, instead of the computing device 106c transmitting commands to the media playback system 100 causing the media playback system 100 to retrieve the requested media from a suitable media service, the computing device 106c itself causes a suitable media service to provide the requested media to the media playback system 100 in accordance with the user's voice utterance.

b. Suitable Playback Devices

FIG. 1C is a block diagram of the playback device 110a comprising an input/output 111. The input/output 111 can include an analog I/O 111a (e.g., one or more wires, cables, and/or other suitable communication links configured to carry analog signals) and/or a digital I/O 111b (e.g., one or more wires, cables, or other suitable communication links configured to carry digital signals). In some embodiments, the analog I/O 111a is an audio line-in input connection comprising, for example, an auto-detecting 3.5 mm audio line-in connection. In some embodiments, the digital I/O 111b comprises a Sony/Philips Digital Interface Format (S/PDIF) communication interface and/or cable and/or a Toshiba Link (TOSLINK) cable. In some embodiments, the digital I/O 111b comprises a High-Definition Multimedia Interface (HDMI) interface and/or cable. In some embodiments, the digital I/O 111b includes one or more wireless communication links comprising, for example, a radio frequency (RF), infrared, WIFI, BLUETOOTH, or another suitable communication link. In certain embodiments, the analog I/O 111a and the digital I/O 111b comprise interfaces (e.g., ports, plugs, jacks) configured to receive connectors of cables transmitting analog and digital signals, respectively, without necessarily including cables.

The playback device 110a, for example, can receive media content (e.g., audio content comprising music and/or other sounds) from a local audio source 105 via the input/output 111 (e.g., a cable, a wire, a PAN, a BLUETOOTH connection, an ad hoc wired or wireless communication network, and/or another suitable communication link). The local audio source 105 can comprise, for example, a mobile device (e.g., a smartphone, a tablet, a laptop computer, etc.) or another suitable audio component (e.g., a television, a desktop computer, an amplifier, a phonograph (such as an LP turntable), a Blu-ray player, a memory storing digital media files). In some aspects, the local audio source 105 includes local music libraries on a smartphone, a computer, a networked-attached storage (NAS), and/or another suitable device configured to store media files. In certain embodiments, one or more of the playback devices 110, NMDs 120, and/or control devices 130 comprise the local audio source 105. In other embodiments, however, the media playback system omits the local audio source 105 altogether. In some embodiments, the playback device 110a does not include an input/output 111 and receives all audio content via the network 104.

The playback device 110a further comprises electronics 112, a user interface 113 (e.g., one or more buttons, knobs, dials, touch-sensitive surfaces, displays, touchscreens, etc.), and one or more transducers 114 (referred to hereinafter as “the transducers 114”). The electronics 112 are configured to receive audio from an audio source (e.g., the local audio source 105) via the input/output 111 or one or more of the computing devices 106a-c via the network 104 (FIG. 1B)), amplify the received audio, and output the amplified audio for playback via one or more of the transducers 114. In some embodiments, the playback device 110a optionally includes one or more microphones 115 (e.g., a single microphone, a plurality of microphones, a microphone array) (hereinafter referred to as “the microphones 115”). In certain embodiments, for example, the playback device 110a having one or more of the optional microphones 115 can operate as an NMD configured to receive voice input from a user and correspondingly perform one or more operations based on the received voice input.

In the illustrated embodiment of FIG. 1C, the electronics 112 comprise one or more processors 112a (referred to hereinafter as “the processors 112a”), memory 112b, software components 112c, a network interface 112d, one or more audio processing components 112g (referred to hereinafter as “the audio components 112g”), one or more audio amplifiers 112h (referred to hereinafter as “the amplifiers 112h”), and power 112i (e.g., one or more power supplies, power cables, power receptacles, batteries, induction coils, Power-over Ethernet (POE) interfaces, and/or other suitable sources of electric power). In some embodiments, the electronics 112 optionally include one or more other components 112j (e.g., one or more sensors, video displays, touchscreens, battery charging bases, etc.).

The processors 112a can comprise clock-driven computing component(s) configured to process data, and the memory 112b can comprise a computer-readable medium (e.g., a tangible, non-transitory computer-readable medium loaded with one or more of the software components 112c) configured to store instructions for performing various operations and/or functions. The processors 112a are configured to execute the instructions stored on the memory 112b to perform one or more of the operations. The operations can include, for example, causing the playback device 110a to retrieve audio data from an audio source (e.g., one or more of the computing devices 106a-c (FIG. 1B)), and/or another one of the playback devices 110. In some embodiments, the operations further include causing the playback device 110a to send audio data to another one of the playback devices 110a and/or another device (e.g., one of the NMDs 120). Certain embodiments include operations causing the playback device 110a to pair with another of the one or more playback devices 110 to enable a multi-channel audio environment (e.g., a stereo pair, a bonded zone, etc.).

The processors 112a can be further configured to perform operations causing the playback device 110a to synchronize playback of audio content with another of the one or more playback devices 110. As those of ordinary skill in the art will appreciate, during synchronous playback of audio content on a plurality of playback devices, a listener will preferably be unable to perceive time-delay differences between playback of the audio content by the playback device 110a and the other one or more other playback devices 110. Additional details regarding audio playback synchronization among playback devices can be found, for example, in U.S. Pat. No. 8,234,395, which is incorporated by reference above.

In some embodiments, the memory 112b is further configured to store data associated with the playback device 110a, such as one or more zones and/or zone groups of which the playback device 110a is a member, audio sources accessible to the playback device 110a, and/or a playback queue with which the playback device 110a (and/or another of the one or more playback devices) can be associated. The stored data can comprise one or more state variables that are periodically updated and used to describe a state of the playback device 110a. The memory 112b can also include data associated with a state of one or more of the other devices (e.g., the playback devices 110, NMDs 120, control devices 130) of the media playback system 100. In some aspects, for example, the state data is shared during predetermined intervals of time (e.g., every 5 seconds, every 10 seconds, every 60 seconds, etc.) among at least a portion of the devices of the media playback system 100, so that one or more of the devices have the most recent data associated with the media playback system 100.

The network interface 112d is configured to facilitate a transmission of data between the playback device 110a and one or more other devices on a data network such as, for example, the links 103 and/or the network 104 (FIG. 1B). The network interface 112d is configured to transmit and receive data corresponding to media content (e.g., audio content, video content, text, photographs) and other signals (e.g., non-transitory signals) comprising digital packet data including an Internet Protocol (IP)-based source address and/or an IP-based destination address. The network interface 112d can parse the digital packet data such that the electronics 112 properly receive and process the data destined for the playback device 110a.

In the illustrated embodiment of FIG. 1C, the network interface 112d comprises one or more wireless interfaces 112e (referred to hereinafter as “the wireless interface 112e”). The wireless interface 112e (e.g., a suitable interface comprising one or more antennae) can be configured to wirelessly communicate with one or more other devices (e.g., one or more of the other playback devices 110, NMDs 120, and/or control devices 130) that are communicatively coupled to the network 104 (FIG. 1B) in accordance with a suitable wireless communication protocol (e.g., WIFI, BLUETOOTH, LTE, etc.). In some embodiments, the network interface 112d optionally includes a wired interface 112f (e.g., an interface or receptacle configured to receive a network cable such as an Ethernet, a USB-A, USB-C, and/or Thunderbolt cable) configured to communicate over a wired connection with other devices in accordance with a suitable wired communication protocol. In certain embodiments, the network interface 112d includes the wired interface 112f and excludes the wireless interface 112e. In some embodiments, the electronics 112 exclude the network interface 112d altogether and transmit and receive media content and/or other data via another communication path (e.g., the input/output 111).

The audio components 112g are configured to process and/or filter data comprising media content received by the electronics 112 (e.g., via the input/output 111 and/or the network interface 112d) to produce output audio signals. In some embodiments, the audio processing components 112g comprise, for example, one or more digital-to-analog converters (DACs), audio preprocessing components, audio enhancement components, a digital signal processors (DSPs), and/or other suitable audio processing components, modules, circuits, etc. In certain embodiments, one or more of the audio processing components 112g can comprise one or more subcomponents of the processors 112a. In some embodiments, the electronics 112 omit the audio processing components 112g. In some aspects, for example, the processors 112a execute instructions stored on the memory 112b to perform audio processing operations to produce the output audio signals.

The amplifiers 112h are configured to receive and amplify the audio output signals produced by the audio processing components 112g and/or the processors 112a. The amplifiers 112h can comprise electronic devices and/or components configured to amplify audio signals to levels sufficient for driving one or more of the transducers 114. In some embodiments, for example, the amplifiers 112h include one or more switching or class-D power amplifiers. In other embodiments, however, the amplifiers 112h include one or more other types of power amplifiers (e.g., linear gain power amplifiers, class-A amplifiers, class-B amplifiers, class-AB amplifiers, class-C amplifiers, class-D amplifiers, class-E amplifiers, class-F amplifiers, class-G amplifiers, class H amplifiers, and/or another suitable type of power amplifier). In certain embodiments, the amplifiers 112h comprise a suitable combination of two or more of the foregoing types of power amplifiers. Moreover, in some embodiments, individual ones of the amplifiers 112h correspond to individual ones of the transducers 114. In other embodiments, however, the electronics 112 include a single one of the amplifiers 112h configured to output amplified audio signals to a plurality of the transducers 114. In some other embodiments, the electronics 112 omit the amplifiers 112h.

The transducers 114 (e.g., one or more speakers and/or speaker drivers) receive the amplified audio signals from the amplifier 112h and render or output the amplified audio signals as sound (e.g., audible sound waves having a frequency between about 20 Hertz (Hz) and 20 kilohertz (kHz)). In some embodiments, the transducers 114 can comprise a single transducer. In other embodiments, however, the transducers 114 comprise a plurality of audio transducers. In some embodiments, the transducers 114 comprise more than one type of transducer. For example, the transducers 114 can include one or more low frequency transducers (e.g., subwoofers, woofers), mid-range frequency transducers (e.g., mid-range transducers, mid-woofers), and one or more high frequency transducers (e.g., one or more tweeters). As used herein, “low frequency” can generally refer to audible frequencies below about 500 Hz, “mid-range frequency” can generally refer to audible frequencies between about 500 Hz and about 2 kHz, and “high frequency” can generally refer to audible frequencies above 2 kHz. In certain embodiments, however, one or more of the transducers 114 comprise transducers that do not adhere to the foregoing frequency ranges. For example, one of the transducers 114 may comprise a mid-woofer transducer configured to output sound at frequencies between about 200 Hz and about 5 kHz.

By way of illustration, Sonos, Inc. presently offers (or has offered) for sale certain playback devices including, for example, a “SONOS ONE,” “PLAY: 1,” “PLAY: 3,” “PLAY: 5,” “PLAYBAR,” “PLAYBASE,” “CONNECT: AMP,” “CONNECT,” “AMP,” “PORT,” and “SUB.” Other suitable playback devices may additionally or alternatively be used to implement the playback devices of example embodiments disclosed herein. Additionally, one of ordinary skill in the art will appreciate that a playback device is not limited to the examples described herein or to Sonos product offerings. In some embodiments, for example, one or more playback devices 110 comprise wired or wireless headphones (e.g., over-the-ear headphones, on-ear headphones, in-ear earphones, etc.). In other embodiments, one or more of the playback devices 110 comprise a docking station and/or an interface configured to interact with a docking station for personal mobile media playback devices. In certain embodiments, a playback device may be integral to another device or component such as a television, an LP turntable, a lighting fixture, or some other device for indoor or outdoor use. In some embodiments, a playback device omits a user interface and/or one or more transducers. For example, FIG. 1D is a block diagram of a playback device 110p comprising the input/output 111 and electronics 112 without the user interface 113 or transducers 114.

FIG. 1E is a block diagram of a bonded playback device 110q comprising the playback device 110a (FIG. 1C) sonically bonded with the playback device 110i (e.g., a subwoofer) (FIG. 1A). In the illustrated embodiment, the playback devices 110a and 110i are separate ones of the playback devices 110 housed in separate enclosures. In some embodiments, however, the bonded playback device 110q comprises a single enclosure housing both the playback devices 110a and 110i. The bonded playback device 110q can be configured to process and reproduce sound differently than an unbonded playback device (e.g., the playback device 110a of FIG. 1C) and/or paired or bonded playback devices (e.g., the playback devices 1101 and 110m of FIG. 1B). In some embodiments, for example, the playback device 110a is a full-range playback device configured to render low frequency, mid-range frequency, and high frequency audio content, and the playback device 110i is a subwoofer configured to render low frequency audio content. In some aspects, the playback device 110a, when bonded with the first playback device, is configured to render only the mid-range and high frequency components of a particular audio content, while the playback device 110i renders the low frequency component of the particular audio content. In some embodiments, the bonded playback device 110q includes additional playback devices and/or another bonded playback device.

c. Suitable Network Microphone Devices (NMDs)

FIG. 1F is a block diagram of the NMD 120a (FIGS. 1A and 1B). The NMD 120a includes one or more voice processing components 124 (hereinafter “the voice components 124”) and several components described with respect to the playback device 110a (FIG. 1C) including the processors 112a, the memory 112b, and the microphones 115. The NMD 120a optionally comprises other components also included in the playback device 110a (FIG. 1C), such as the user interface 113 and/or the transducers 114. In some embodiments, the NMD 120a is configured as a media playback device (e.g., one or more of the playback devices 110), and further includes, for example, one or more of the audio components 112g (FIG. 1C), the amplifiers 112h, and/or other playback device components. In certain embodiments, the NMD 120a comprises an Internet of Things (IOT) device such as, for example, a thermostat, alarm panel, fire and/or smoke detector, etc. In some embodiments, the NMD 120a comprises the microphones 115, the voice processing components 124, and only a portion of the components of the electronics 112 described above with respect to FIG. 1B. In some aspects, for example, the NMD 120a includes the processor 112a and the memory 112b (FIG. 1B), while omitting one or more other components of the electronics 112. In some embodiments, the NMD 120a includes additional components (e.g., one or more sensors, cameras, thermometers, barometers, hygrometers, etc.).

In some embodiments, an NMD can be integrated into a playback device. FIG. 1G is a block diagram of a playback device 110r comprising an NMD 120d. The playback device 110r can comprise many or all of the components of the playback device 110a and further include the microphones 115 and voice processing components 124 (FIG. 1F). The playback device 110r optionally includes an integrated control device 130c. The control device 130c can comprise, for example, a user interface (e.g., the user interface 113 of FIG. 1B) configured to receive user input (e.g., touch input, voice input, etc.) without a separate control device. In other embodiments, however, the playback device 110r receives commands from another control device (e.g., the control device 130a of FIG. 1B).

Referring again to FIG. 1F, the microphones 115 are configured to acquire, capture, and/or receive sound from an environment (e.g., the environment 101 of FIG. 1A) and/or a room in which the NMD 120a is positioned. The received sound can include, for example, vocal utterances, audio played back by the NMD 120a and/or another playback device, background voices, ambient sounds, etc. The microphones 115 convert the received sound into electrical signals to produce microphone data. The voice processing components 124 receive and analyze the microphone data to determine whether a voice input is present in the microphone data. The voice input can comprise, for example, an activation word followed by an utterance including a user request. As those of ordinary skill in the art will appreciate, an activation word is a word or other audio cue signifying a user voice input. For instance, in querying the AMAZON VAS, a user might speak the activation word “Alexa.” Other examples include “Ok, Google” for invoking the GOOGLE VAS and “Hey, Siri” for invoking the APPLE VAS.

After detecting the activation word, voice processing components 124 monitor the microphone data for an accompanying user request in the voice input. The user request may include, for example, a command to control a third-party device, such as a thermostat (e.g., NEST thermostat), an illumination device (e.g., a PHILIPS HUE lighting device), or a media playback device (e.g., a SONOS playback device). For example, a user might speak the activation word “Alexa” followed by the utterance “set the thermostat to 68 degrees” to set a temperature in a home (e.g., the environment 101 of FIG. 1A). The user might speak the same activation word followed by the utterance “turn on the living room” to turn on illumination devices in a living room area of the home. The user may similarly speak an activation word followed by a request to play a particular song, an album, or a playlist of music on a playback device in the home.

d. Suitable Control Devices

FIG. 1H is a partial schematic diagram of the control device 130a (FIGS. 1A and 1B). As used herein, the term “control device” can be used interchangeably with “controller” or “control system.” Among other features, the control device 130a is configured to receive user input related to the media playback system 100 and, in response, cause one or more devices in the media playback system 100 to perform an action(s) or operation(s) corresponding to the user input. In the illustrated embodiment, the control device 130a comprises a smartphone (e.g., an iPhone™M, an Android phone, etc.) on which media playback system controller application software is installed. In some embodiments, the control device 130a comprises, for example, a tablet (e.g., an iPad™), a computer (e.g., a laptop computer, a desktop computer, etc.), and/or another suitable device (e.g., a television, an automobile audio head unit, an IoT device, etc.). In certain embodiments, the control device 130a comprises a dedicated controller for the media playback system 100. In other embodiments, as described above with respect to FIG. 1G, the control device 130a is integrated into another device in the media playback system 100 (e.g., one more of the playback devices 110, NMDs 120, and/or other suitable devices configured to communicate over a network).

The control device 130a includes electronics 132, a user interface 133, one or more speakers 134, and one or more microphones 135. The electronics 132 comprise one or more processors 132a (referred to hereinafter as “the processors 132a”), a memory 132b, software components 132c, and a network interface 132d. The processor 132a can be configured to perform functions relevant to facilitating user access, control, and configuration of the media playback system 100. The memory 132b can comprise data storage that can be loaded with one or more of the software components executable by the processor 132a to perform those functions. The software components 132c can comprise applications and/or other executable software configured to facilitate control of the media playback system 100. The memory 132b can be configured to store, for example, the software components 132c, media playback system controller application software, and/or other data associated with the media playback system 100 and the user.

The network interface 132d is configured to facilitate network communications between the control device 130a and one or more other devices in the media playback system 100, and/or one or more remote devices. In some embodiments, the network interface 132d is configured to operate according to one or more suitable communication industry standards (e.g., infrared, radio, wired standards including IEEE 802.3, wireless standards including IEEE 802.11a, 802.11b, 802.11g, 802.11n, 802.11ac, 802.15, 4G, LTE, etc.). The network interface 132 d can be configured, for example, to transmit data to and/or receive data from the playback devices 110, the NMDs 120, other ones of the control devices 130, one of the computing devices 106 of FIG. 1B, devices comprising one or more other media playback systems, etc. The transmitted and/or received data can include, for example, playback device control commands, state variables, playback zone and/or zone group configurations. For instance, based on user input received at the user interface 133, the network interface 132d can transmit a playback device control command (e.g., volume control, audio playback control, audio content selection, etc.) from the control device 130a to one or more of the playback devices 110. The network interface 132d can also transmit and/or receive configuration changes such as, for example, adding/removing one or more playback devices 110 to/from a zone, adding/removing one or more zones to/from a zone group, forming a bonded or consolidated player, separating one or more playback devices from a bonded or consolidated player, among others.

The user interface 133 is configured to receive user input and can facilitate control of the media playback system 100. The user interface 133 includes media content art 133a (e.g., album art, lyrics, videos, etc.), a playback status indicator 133b (e.g., an elapsed and/or remaining time indicator), media content information region 133c, a playback control region 133d, and a zone indicator 133e. The media content information region 133c can include a display of relevant information (e.g., title, artist, album, genre, release year, etc.) about media content currently playing and/or media content in a queue or playlist. The playback control region 133d can include selectable (e.g., via touch input and/or via a cursor or another suitable selector) icons to cause one or more playback devices in a selected playback zone or zone group to perform playback actions such as, for example, play or pause, fast forward, rewind, skip to next, skip to previous, enter/exit shuffle mode, enter/exit repeat mode, enter/exit cross fade mode, etc. The playback control region 133d may also include selectable icons to modify equalization settings, playback volume, and/or other suitable playback actions. In the illustrated embodiment, the user interface 133 comprises a display presented on a touch screen interface of a smartphone (e.g., an iPhone™, an Android phone, etc.). In some embodiments, however, user interfaces of varying formats, styles, and interactive sequences may alternatively be implemented on one or more network devices to provide comparable control access to a media playback system.

The one or more speakers 134 (e.g., one or more transducers) can be configured to output sound to the user of the control device 130a. In some embodiments, the one or more speakers comprise individual transducers configured to correspondingly output low frequencies, mid-range frequencies, and/or high frequencies. In some aspects, for example, the control device 130a is configured as a playback device (e.g., one of the playback devices 110). Similarly, in some embodiments the control device 130a is configured as an NMD (e.g., one of the NMDs 120), receiving voice commands and other sounds via the one or more microphones 135.

The one or more microphones 135 can comprise, for example, one or more condenser microphones, electret condenser microphones, dynamic microphones, and/or other suitable types of microphones or transducers. In some embodiments, two or more of the microphones 135 are arranged to capture location information of an audio source (e.g., voice, audible sound, etc.) and/or configured to facilitate filtering of background noise. Moreover, in certain embodiments, the control device 130a is configured to operate as a playback device and an NMD. In other embodiments, however, the control device 130a omits the one or more speakers 134 and/or the one or more microphones 135. For instance, the control device 130a may comprise a device (e.g., a thermostat, an IoT device, a network device, etc.) comprising a portion of the electronics 132 and the user interface 133 (e.g., a touch screen) without any speakers or microphones.

### III. Port Contamination Detection Discussion

According to various embodiments, playback devices such as those described herein can be configured to receive both audio data and line power via a powered communication port, such as a USB port, for example. In such examples, the communication port can include a multi-pin connector having one or more pins configured to receive power (“power pins”) and one or more pins configured to receive data (“data pins”). As discussed above, in some circumstances, particularly where the playback device is a portable playback device, the communication port can become contaminated such that an electrical short is created between two or more pins of the multi-pin connector, which can cause damage to the playback device and/or its charging cable. Accordingly, aspects and embodiments are directed to playback devices, and methods of operating the playback devices, that can detect potential contamination of the charging port of the playback device and optionally alert a user to take appropriate action.

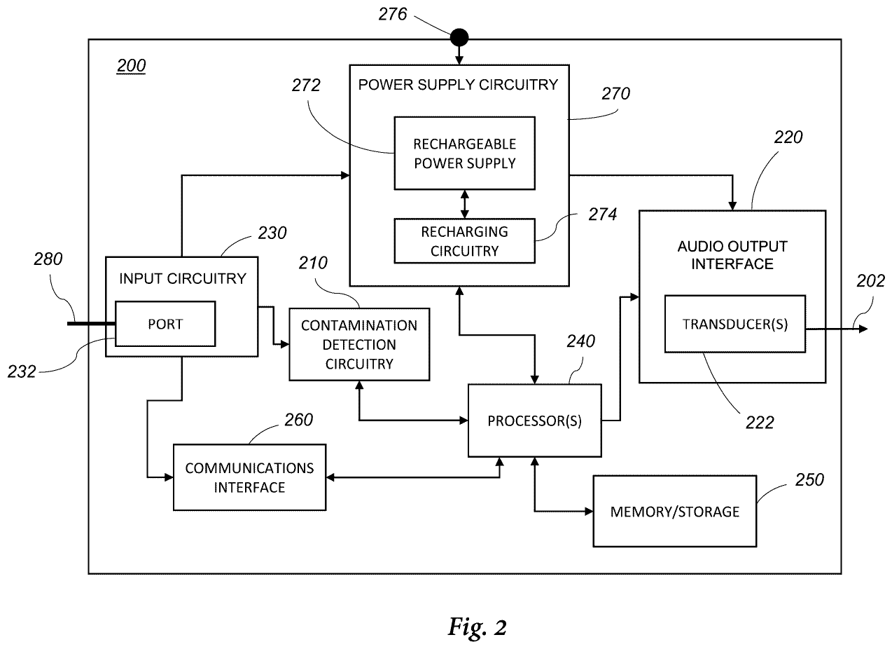

Referring to FIG. 2, there is illustrated a block diagram of one example of a playback device 200 including contamination detection circuitry 210 according to aspects disclosed herein. The playback device 200 may be used to implement any of the playback devices 110 discussed above, for example. The playback device 200 includes an audio output interface 220 and input circuitry 230. As discussed above, the playback device 200 is generally configured to drive one or more transducers 222 (e.g., speakers) in the audio output interface 220 based on audio data received via the input circuitry 230 to provide an acoustic output 202 that corresponds to playback of audio content included in the received audio data. The input circuitry 230 includes an input port 232. In examples where the playback device 200 is configured to receive audio data and power over a combined power/communication line such as a USB cable 280 (referred to herein as a multi-function cable), the input port 232 may be a multi-pin connector such as, for example, a USB-A, USB-B, or USB-C connector. In various examples, the multi-pin connector is a USB receptacle configured to receive and mate with a corresponding USB connector on the USB multi-function cable 280.

The playback device 200 includes one or more processors 240 (such as processors 112a discussed above) configured to control operation of the playback device as discussed above. The processor(s) 240 can be operably coupled to a tangible, non-transitory computer-readable memory 250 that stores program instructions that are executable by the one or more processors 240 such that the one or more processors are configured to control operations of various components of the playback device circuitry and to perform functions in accord with aspects and features discussed herein. The one or more processor(s) 240 are operably coupled to the audio output interface 220, as shown in FIG. 2.

In certain examples, the playback device 200 includes a communications interface 260 operably coupled between the input port 232 and the processor(s) 240. The communications interface 260 can be operably connected to the processor(s) 240 and can be configured to perform digital signal processing on data received from the input port 232 to produce a processed audio data stream. Although shown in FIG. 2 as separate from the input circuitry 230, in some embodiments, the communications interface 260 may be partially or wholly implemented as part of the input circuitry 230. In certain examples, the communications interface 260 may include a wireless interface configured to receive and/or transmit wireless signals, including audio data streams, for example.

Still referring to FIG. 2, the playback device 200 may further include power supply circuitry 270 operably coupled between the input circuitry 230 and the audio output interface 220 and operably coupled to the processor(s) 240. The power supply circuitry 270 can be configured to condition the power received from the input port 232 to provide power to various components of the playback device 200. In certain examples, the playback device 200 may further include a power port 276 for receiving line power in addition to having the capability to receive power via the multi-function cable 280. Accordingly, the power supply circuitry 270 may be coupled to the power port 276 to receive and condition electrical power, as discussed above. The power supply circuitry includes a rechargeable power supply 272 configured to provide power to the playback device. The rechargeable power supply 272 may include one or more rechargeable power sources, such as one or more rechargeable batteries (e.g., rechargeable lithium batteries, for example). The power supply circuitry 270 further includes recharging circuitry 274 operably coupled between the input circuitry and the rechargeable power supply 272. The recharging circuitry 274 can be configured to receive and condition the charging power from the input circuitry 230 and provide the conditioned charging power to the rechargeable power supply 272.

In certain embodiments, at least one of the power supply circuitry 270 and/or the audio output interface 220 may include one or more amplifiers (such as amplifiers 112h discussed above) configured to provide an amplified audio data stream to the one or more transducers 222 so as to drive the transducer(s) 222 to produce the acoustic output 202. In certain examples, the power supply circuitry 270 can be configured to provide conditioned power to the amplifier(s) from the input circuitry 230. The processor(s) 240 can be configured to provide a digital signal to the amplifier(s) including the processed audio data stream from the communications interface 260 to the amplified by the amplifier(s) and output to the transducer(s) 222.

In certain examples, the processor(s) 240 can be configured to receive a first audio stream via the input circuitry 230 and cause the playback device 200 to play back audio content based on the first audio stream via the audio output interface 220. In examples in which the communications interface 260 includes a wireless communications interface, as discussed above, the processor(s) 240 may be configured to generate a second audio stream based on the first audio stream, and transmit the second audio stream to at least one other playback device via wireless communication interfaces. The at least one other playback device can be configured to play back audio content based on the second audio stream in synchrony with playback of the audio content based on the first audio stream by the playback device 200, as discussed above.

Embodiments of the playback device 200 can receive (in addition to charging power) various different types of data via the multi-function cable 280 coupled to the input port 232, including audio data containing audio content for playback by the playback device 200. For example, a first end of the multi-function cable 280 may include a first USB-type connector, such as a USB-C connector, for connecting to the input port 232 of the playback device 200. The other end of the multi-function cable 280 may include a second USB-type connector that can be connected to an electronic device (which may provide audio data and optionally charging power) or via a transformer to a mains power supply, for example. When connected to a device that can supply audio data via the multi-function cable 280, the playback device can be configured to handle the incoming audio data on the multi-function cable 280 as an audio line-in input connection, as discussed above with reference to FIG. 1C, for example. The playback device 200 may play back the received audio content and/or transmit some or all of the audio content to other playback devices via the communications interface 260.

Thus, as discussed above with reference to FIGS. 1A-H, embodiments of the playback device 200 can receive audio data via the input port 232, perform various processing of the received audio data, and play back audio content included in the audio data to provide the acoustic output 202 via the audio output interface 220. In addition, embodiments of the playback device 200 can produce additional audio data based on the received audio data and transmit that additional audio data to one or more other playback devices via the communications interface 206 for synchronous playback. Further, in certain embodiments, the playback device 200 may produce the acoustic output 202 corresponding to the additional audio data and play back the acoustic output 202 in synchrony with the one or more other playback devices.

As discussed above, in certain instances the input port 232 can become contaminated, which could result in damage to the playback device 200 and/or the multi-function cable 280. Accordingly, embodiments of the playback device 200 include contamination detection circuitry 210 configured to detect when the input port 232 becomes contaminated. The contamination detection circuitry 210 is operably coupled between the input circuitry 230 and the processor(s) 240. As discussed in more detail below, the contamination detection circuitry 210 can be configured to monitor an impedance between one or more pins of the input port 232 and a known reference and to output a contamination signal indicating a state of contamination of the multi-pin connector based on the monitored impedance.

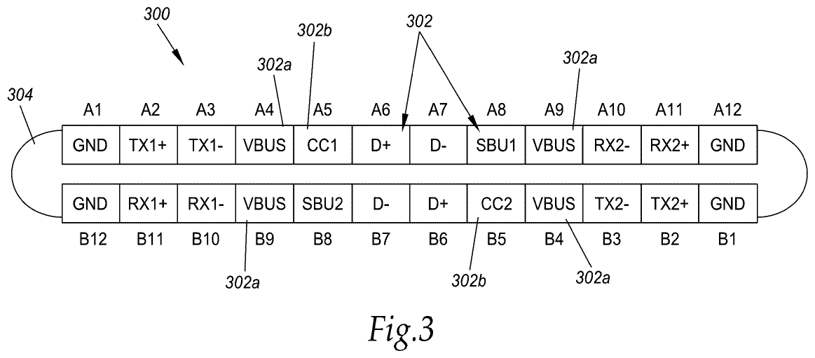

Referring to FIG. 3, there is illustrated an example of a multi-pin connector 300 that may be used as the input port 232 in certain embodiments. In the illustrated example, the multi-pin connector 300 is a USB-C connector; however, those skilled in the art will appreciate, given the benefit of this disclosure, that the principles, features, and functions discussed herein may be applied and implemented using other types of multi-pin connectors, and embodiments of the input port 232 are not limited to USB-C connectors. The multi-pin connector 300 includes a plurality of pins 302 arranged in a housing 304. In the example illustrated in FIG. 3, the multi-pin connector 300 includes 24 pins 302 arranged in two parallel rows and labeled A1-A12 and B1-B12. As discussed above, the multi-pin connector 300 may include a plurality of power pins that receive electrical power from the multi-function cable 280 and a plurality of data pins that carry various audio and/or other data signals. In the example illustrated in FIG. 3, the multi-pin connector 300 includes four power pins 302a labeled “VBUS” (located at positions A4, A9, B4, and B9 in the illustrated example) that receive charging power for the playback device 200 via the multi-function cable 280. In certain examples, various other pins 302 may also carry power signals; however, for the purposes of illustration and explanation, the following discussion will refer primarily to the VBUS power pins 302a. In the illustrated example, the multi-pin connector 300 also includes two data pins 302b labeled “CC1” and “CC2” (located at positions A5 and B5) that carry certain data signals. The CC data pins 302b are channel configuration pins that are used for a variety of purposes to setup the communication/power delivery channel for the playback device 200, such as detecting attach/detach events with the multi-function cable 280 and negotiating parameters for power delivery (e.g., the voltage level at which to set VBUS), for example. Those skilled in the art will appreciate that various other pins 302 of the multi-pin connector 300 may also be data pins (e.g., the pins 302 at positions A2, A3, A10, A11, B2, B3, B10, and B11 in the illustrated example may carry audio data signals including the incoming audio data stream to be processed by the playback device 200). In a USB-C multi-pin connector, such as that illustrated in FIG. 3, the CC data pins 302b are located directly adjacent to VBUS power pins 302a. As a result, contamination of the USB-C port can easily cause an electrical short between these adjacent pins. Furthermore, an electrical short of the CC data pins 302b to the VBUS power pins 302a may be likely to cause damage due to overheating, for example. Accordingly, the following discussion may refer primarily to the CC data pins 302b; however, the processes and features discussed herein may be applied to any pins 302 of the multi-pin connector 300, as will be readily appreciated by those skilled in the art, given the benefit of this disclosure.

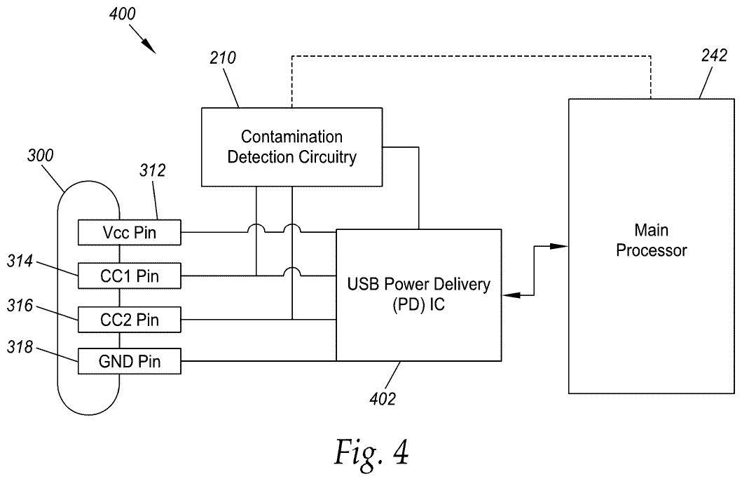

According to certain embodiments, the contamination detection circuitry 210 may be coupled to those one or more data pins 302 to be monitored. FIG. 4 is a block diagram of circuitry 400, illustrating an example of the contamination detection circuitry connected to components of the playback device 200. In the example shown in FIG. 4, the contamination detection circuitry is coupled to the CC data pins 302b, represented individually as CC1 pin 314 and CC2 pin 316, to monitor the impedance of those pins to a known reference. The contamination detection circuitry is further coupled to a processor 242, which may be one of the one or more processors 240 discussed above, and to a USB power delivery microcontroller 402, which may be part of the power supply circuitry 270 and/or one of the one or more processors 240. The CC data pins 314, 316 are coupled to the USB power delivery microcontroller 402. A VBUS power pin 312 of the multi-pin connector 300 and a ground pin 318 of the multi-pin connector 300 are also coupled to the USB power delivery microcontroller 402, as shown in FIG. 4. The USB power delivery microcontroller 402 is operably coupled to and in communication with the processor 242.

In certain examples, the CC data pins 314, 316 are connected to the USB power delivery microcontroller 402 for power delivery negotiation communications for the playback device 200. Similarly, the connections of the pins 312 and 318 to the USB power delivery microcontroller 402 may be existing connections used for operation of the playback device 200. Accordingly, embodiments of the circuitry 400 leverage these existing connections to simplify or reduce the additional circuitry needed to perform impedance measurements to monitor for contamination in the multi-pin connector 300, as discussed further below. As noted above, one technical challenge in measuring the impedance between the CC data pins 314, 316 and VBUS (pin 312) or Ground (pin 318) is that the voltage across the CC 314, 316 may be frequently changing to communicate information (for example, to negotiate power delivery). For example, the CC data pins 314, 316 may vary between a Logic High (e.g., 1) and a Logic Low (e.g., 0) state at a rate of approximately 10-15 kilohertz (kHz), for example at about 12 kHz. To avoid interrupting the communication over the CC data pins 314, 316, the circuitry 400 can be configured to induce a test current through the CC data pins 314, 316 and a known resistance to either the VBUS pin 312 or ground pin 318 and measure a differential voltage across the known resistance to determine the magnitude of this test current. Measuring differential voltage accounts for the voltage fluctuations of the CC data pins 314, 316 during operation. The magnitude of this test current provides an indication of the impedance between the CC data pins 314, 316, and the VBUS pin 312 or ground pin 318. Under normal conditions, there may be some connection between the CC data pins 314, 316 and the VBUS pin 312 and/or ground pin 318 through the USB power delivery microcontroller 402 and/or the processor 242 (or through the input circuitry 230). However, the impedance of these connections normally would be very high (e.g., several kiloOhms (kΩ)). Accordingly, detection of a low impedance in one or more of these connections may provide a good indication of contamination of the multi-pin connector.

The contamination detection circuitry 210 may output a contamination signal to the processor 242 that indicates a state of contamination of the multi-pin connector 300 (and therefore of the input port 232). The contamination signal may include any of various different items of information that indicate the state of contamination. In certain examples, the contamination signal may include a measurement of the test current discussed above. In such examples, the processor 242 may determine the impedance value, or an indication of the impedance, based on the current measurement received in the contamination signal. In certain examples, the processor 242 may determine an actual value of the impedance and compare the value against a predetermined threshold value to determine whether an electrical short between pins (and therefore contamination of the multi-pin connector 300) has been detected. In other examples, the processor 242 may determine whether the impedance is “high” or “low” as defined by predetermined ranges or values set within the programming of the processor 242, and determine the corresponding state of contamination (e.g., the impedance being “low” indicates that the input port 232 is contaminated). In other examples, the contamination signal may simply indicate a Logic High or Logic Low, with a Logic Low signaling contamination and a Logic High signaling that the impedance between the monitored pins is within an expected normal range (e.g., no electrical short and therefore no contamination detected), or vice versa. Thus, the information communicated to the processor 242 via the contamination signal from the contamination detection circuitry 210 may vary depending on the configuration of the circuitry 400. However, in each instance, the processor 242 may receive information from the contamination detection circuitry that indicates the state of contamination (e.g., contaminated or not contaminated) of the input port 232.

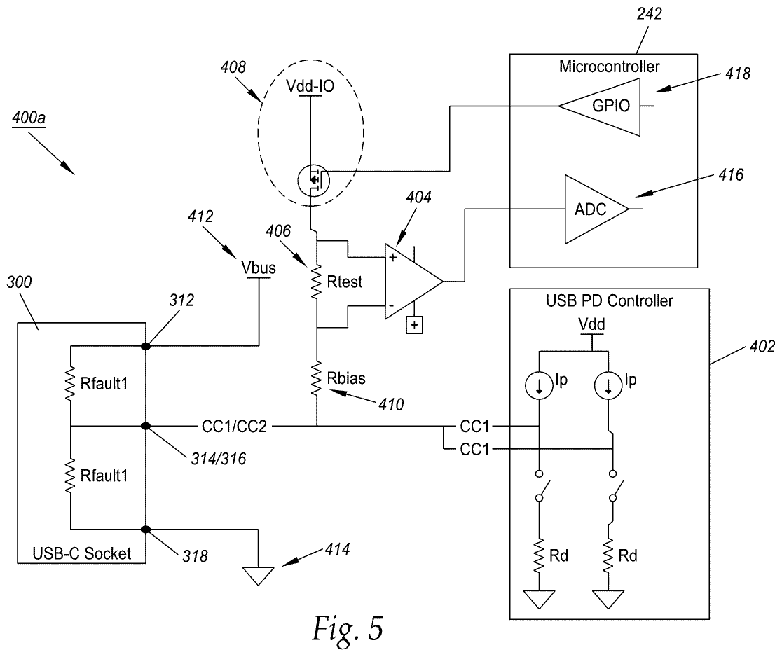

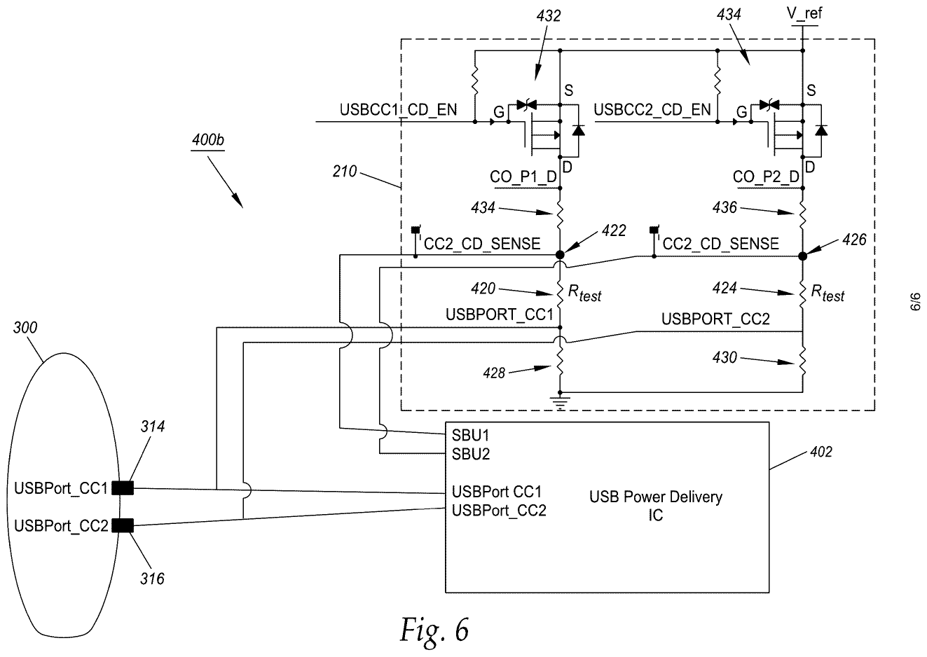

FIGS. 5 and 6 illustrate examples of implementations of the circuitry 400 according to certain embodiments.

Referring to FIG. 5, in one example, the circuitry 400a includes a differential operational amplifier 404 coupled to the processor 242 and to the USB power delivery microcontroller 402. A test resistor 406 is connected between the two inputs of the operational amplifier 404. A first input of the operational amplifier 404 is connected to a current source 408, and a second input of the operational amplifier 404 is connected via a bias resistor 410 to the CC data pins 314, 316. In the example shown in FIG. 5, the connection to the CC data pins 314, 316 is shown with a common line and switching circuitry within the USB power delivery microcontroller 402 is used to individually select one CC pin or the other; however, those skilled in the art will appreciate that various other connection arrangements may be implemented. For measurement purposes, one of the CC data pins 314 or 316 is connected at any given time to the second input of the operational amplifier 404 via the bias resistor 410 such that individual impedance measurements for each CC pin 314, 316 relative to a reference voltage, such as VBUS 412 or ground 414 can be made. The output of the operational amplifier 404 is coupled to the processor 242. The current source 408, optionally under the control of the processor 242, may induce a test current through the test resistor 406 and through the bias resistor 410 to the connected CC pin 314 or 316. Thus, the operational amplifier 404, the current source 408, the test resistor 406, and the bias resistor 410 may all form part of the contamination detection circuitry 210.

The operational amplifier 404 may measure the differential voltage across the test resistor 406, which in turn provides a measurement of the magnitude of the test current. Given known resistance values of the test resistor 406 and the bias resistor 410, the magnitude of the test current provides a measurement of the impedance from the connected CC pin 314, 316 to a voltage reference point, namely VBUS 412 or ground 414. As discussed above, measuring the impedance of the CC pin 314, 316 to VBUS 412 can provide an indication of whether there exists a low impedance condition, such as an electrical short, between one of the CC data pins 302b and one of the VBUS power pins 302 (the specific pin pair being determined by the electrical connections established in the circuitry 400a) in the multi-pin connector 300, which may be caused by contamination of the multi-pin connector 300.

The resistance value of the test resistor 406 may be selected or tuned to an appropriate value/range based on the known expected impedance between the CC data pins 302b and the VBUS pins 302a under normal conditions (i.e., no contamination of the multi-pin connector 300) and the known expected impedance in the case of a fault or short condition. In certain examples, the test resistor 406 may have a resistance value in a range of 5 kΩ to 50 kΩ, for example, approximately 10 kΩ. The bias resistor 410 may act as a pull-up resistor, and its resistance value may be chosen accordingly. In certain examples, the resistance value of the bias resistor 410 may be in a range of 10 kΩ to 10,000 kΩ, for example.

Still referring to FIG. 5, in some examples, the processor 242 may include an analog-to-digital converter (ADC) 416 that receives the output from the differential operational amplifier 404 (which in some instances may correspond to the contamination signal discussed above) and convert that output to a digital value. In some instances, the output from the ADC 416 may be a Logic High or a Logic Low, with one value indicating an impedance event representative of an electrical short at the measured CC pin 314, 316 and the other indicating a normal or expected impedance associated with no contamination of the input port 232. In certain examples, the processor 242 may be configured to receive an impedance value based on the differential voltage measurement, compare that impedance value to a known expected value (e.g., an expected high impedance value as discussed above), and determine if the difference (i.e., change in impedance between the monitored pins) indicates a potential electrical short. In some examples, the processor 242 may make a determination about the impedance based on the averaged value of several data samples from the ADC 416. Although the ADC 416 is illustrated in the example of FIG. 5 as being part of the processor 242, in other examples, the ADC 416 may be part of the contamination detection circuitry 210 and its output may be provided to the processor 242 as the contamination signal.

As discussed above, in certain examples, the current source 408 can be operated under the control of the processor 242. For example, the processor 242 may include a general-purpose input/output driver 418 to drive the current source 408 to induce the test current when impedance/contamination measurements are to be made. For example, in certain instances, contamination detection may be performed during the handshake procedures that occur when the playback device 200 is plugged in for charging via the multi-function cable 280. Accordingly, the processor 242 may activate the current source 408 to induce the test current at the appropriate time for measurements to be made and turn it off at other times.

In the example implementation of FIG. 5, the differential voltage measurements are achieved using the differential operational amplifier 404. According to certain examples, the USB power delivery microcontroller 402 may include a differential analog-to-digital converter (ADC) that can be configured to measure a voltage relative to the CC data pins 314, 316. As discussed above, the CC data pins 314, 316 may be already connected to the USB power delivery microcontroller 402 to negotiate power delivery. In such implementations, the differential ADC in the USB power delivery microcontroller 402 can be leveraged to measure the voltage drop across known test resistors and thereby provide an indication of the impedance at the CC data pins 314, 316. FIG. 6 illustrates an example of a portion of the circuitry 400 configured for such an implementation.

Referring to FIG. 6, in this example, the circuitry 400b includes a first test resistor 420 connected between the first CC data pin 314 and a first measurement/sensing node 422, and a second test resistor 424 connected between the second CC data pin 316 and a second measurement/sensing node 426. The sensing nodes 422, 426 are coupled to contacts on the USB power delivery microcontroller 402 labeled SBU1 and SBU2, respectively in FIG. 6. In certain examples, these contacts are also coupled to SBU1 and SBU2 pins 302 (see FIG. 3) in the multi-pin connector 300. Bias resistors 428, 430 may be coupled between the first and second test resistors 420, 424, respectively, and a reference such as ground, as shown in FIG. 6. The contamination detection circuitry 210 may include a first current source 432 configured to induce a test current through the first test resistor 420, and a second current source 434 configured to induce a test current through the second test resistor 424. In certain examples, additional bias resistors 436, 438 may be coupled between the first and second current sources 432, 434 and the first and second sensing nodes 422, 426, respectively, as shown in FIG. 6.

In the example shown in FIG. 6, the circuitry 400b includes individual current sources, test resistors, and bias resistors for each of the two CC data pins 314, 316; however, those skilled in the art will appreciate, given the benefit of this disclosure, that in other examples, switching or other multiplexing circuitry may be used to share any one or more of a current source, test resistor, and/or bias resistor for measurements on both CC data pins 314, 316, and/or for measurements with respect to any other pins 302 of the multi-pin connector 300.

Internally within the USB power delivery microcontroller 402, the contacts SBU1, SBU2 and contacts corresponding to the CC data pins 314, 316 may be connected to the differential ADC (not shown in FIG. 6) which is configured to measure the differential voltages across the first and second test resistors 420, 424, as discussed above. Because the differential ADC has differential inputs, the use of the operational amplifier 404 of the implementation of FIG. 5 can be avoided. The output from the differential ADC within the USB power delivery microcontroller 402 is indicative of the impedance conditions at the measured CC data pin 314, 316, similar to the output of the ADC 416 discussed above with reference to FIG. 5. Although not shown as such in FIG. 6, in certain examples of the implementation shown in FIG. 6, the USB power delivery microcontroller 402 may be considered part of the contamination detection circuitry 210 and may supply the contamination signal (which may include the output of the USB power delivery microcontroller's differential ADC or a signal based thereon) to the processor 242.

The above-discussed examples illustrate how the contamination detection circuitry 210 and processor(s) 240 can be configured to detect and respond to contamination of the input port 232 based on detecting an impedance change signaling an electrical short between at least one VBUS power pin 302a and at least one CC data pin 302b. Those skilled in the art will readily appreciate, given the benefit of this disclosure, that the circuitry 400 and operating instructions for the processor(s) 240 can be easily adapted to detect impedance changes signaling an electrical short between any other pairs or combinations of data pins and power pins in the multi-pin connector 300.

Following receipt of the contamination signal from the contamination detection circuitry 210, and any processing thereof that the processor 242 may perform, if an impedance condition indicating contamination of the input port 232 has been detected, the processor 242 may take any of several actions. For example, the processor 242 may cause an alert to be provided to advise a user of the playback device 200 that the input port 232 may be contaminated. In certain examples, the processor 242 may provide a signal to a playback system controller, such as the control device 130a discussed above, which may alert the user via a software application running on the control device 130. In other examples, the processor 242 may cause the playback device 200 to produce an alert, such as a solid or flashing light or an audio tone, to indicate to the user that contamination of the input port 232 has been detected.

As discussed above, in certain examples, contamination detection may be performed during the handshake procedures that occur when the playback device 200 is plugged in for charging via the multi-function cable 280. If contamination is detected, the processor 242 may cause the alert to be provided, warning a user to unplug the playback device 200 and check the input port 232. In some examples, the processor 242 can be configured to coordinate with the USB power delivery microcontroller 402 and/or other components of the power supply circuitry 270 to shut off charging power to the playback device 200, or otherwise prevent the playback device 200 from receiving power via the power pins 302a of the multi-pin connector 300, until the user takes some action to clear the contamination fault, so as to prevent damage to the playback device 200 and/or the multi-function cable 280. In other examples, contamination detection may be performed continuously or periodically while the playback device is not plugged in for charging. In such examples, if contamination is detected, the user can be alerted and warned not to plug in the playback device 200 for charging until remedial action has been taken, so as to avoid damaging the playback device.

In certain examples, the processor 242 may be configured to determine whether the multi-function cable 280 is connected to the input port 232 and to an external power source to supply charging power to the playback device 200. If the multi-function cable 280 is not connected, the processor 242 may: (i) control the contamination detection circuitry 210 to perform contamination detection measurements; and/or (ii) process the contamination signal, according to a first processing schedule. If the multi-function cable 280 is connected, the processor 242 may: (i) control the contamination detection circuitry 210 to perform contamination detection measurements; and/or (ii) process the contamination signal, according to a second processing schedule that involves performing the actions (i) and/or (ii) more frequently than according to the first processing schedule. The playback device 200 may be in more danger of damage occurring due to contamination of the input 232 when the multi-function cable 280 is connected and able to supply power to the playback device. Therefore, in these conditions, the processor 242 may monitor for potential port contamination more frequently.

In addition to the playback device 200 being configured to cause alerts to be provided or take other actions (such as preventing receipt of power as discussed above) based on contamination of the input port 232 being detected, in certain embodiments, the multi-function cable 280 may be provided with a mechanism to prevent or mitigate damage in the event of an electrical short existing in the input port 232. For example, the multi-function cable 280 may include a resettable fuse that is configured to have an impedance that increases with temperature (e.g., a positive temperature coefficient (PTC) fuse) and thereby limits current flow through the cable when the cable gets too hot, as may be the case in the presence of an electrical short to one of the power pins as discussed above.

Thus, aspects and embodiments provide methods and apparatus for monitoring the impedance at any selected one or more pins of a multi-pin connector to identify potential contamination of the connector, and for signaling an alert and/or taking other actions upon detection of contamination so as to avoid damaging the playback device and/or charging cable associated with the contaminated connector.

### IV. Conclusion

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the examples disclosed herein. Accordingly, the foregoing description and drawings of various embodiments are presented by way of example only. These examples are not intended to be exhaustive or to limit implementation to the precise forms disclosed. The methods and apparatuses are capable of implementation in other embodiments and of being practiced or of being carried out in various ways.

The above discussions relating to playback devices, controller devices, playback zone configurations, and media content sources provide only some examples of operating environments within which functions and methods described below may be implemented. Other operating environments and configurations of media playback systems, playback devices, and network devices not explicitly described herein may also be applicable and suitable for implementation of the functions and methods.

The description above discloses, among other things, various example systems, methods, apparatus, and articles of manufacture including, among other components, firmware and/or software executed on hardware. Such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only ways to implement such systems, methods, apparatus, and/or articles of manufacture.

In addition, the phraseology and terminology used herein is for the purpose of description and should not be regarded as limiting. Any references to examples, components, elements, or acts of the systems and methods herein referred to in the singular can also embrace examples including a plurality, and any references in plural to any example, component, element or act herein can also embrace examples including only a singularity. References in the singular or plural form are not intended to limit the presently disclosed systems or methods, their components, acts, or elements. The use herein of “including”, “comprising”, “having”, “containing”, “involving”, and variations thereof is meant to encompass the items listed thereafter and equivalents thereof as well as additional items. References to “or” can be construed as inclusive so that any terms described using “or” can indicate any of a single, more than one, and all of the described terms.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

### V. EXAMPLES

(Example 1) A playback device comprising: one or more processors; an audio output interface operably connected to the one or more processors and configured to output audio; one or more rechargeable power sources configured to provide power to the playback device; input circuitry including a multi-pin connector configured to receive both charging power and data; contamination detection circuitry operably coupled to the one or more processors and to at least a portion of the multi-pin connector, the contamination detection circuitry configured to output a contamination signal indicating a state of contamination of the multi-pin connector; a tangible, non-transitory computer-readable memory operably connected to the one or more processors and including program instructions that are executable by the one or more processors such that the one or more processors are configured to: detect the contamination signal from the contamination detection circuitry; and cause an alert to be provided based on the state of contamination of the multi-pin connector being contaminated.
(Example 2) The playback device of Example 1, further comprising recharging circuitry operably connected to the input circuitry and configured to: receive and condition the charging power from the input circuitry; and provide the conditioned charging power to the one or more rechargeable power sources.
(Example 3) The playback device of Example 2, wherein the tangible, non-transitory computer-readable memory further includes program instructions that are executable by the one or more processors such that the one or more processors are configured to cause at least a portion of the recharging circuitry to turn off based on the state of contamination of the multi-pin connector being contaminated.
(Example 4) The playback device of Example 2, wherein the multi-pin connector comprises: one or more data pins configured to receive and transfer at least a portion of the data to the one or more processors; and one or more power pins configured to receive and transfer at least a portion of the charging power to the recharging circuitry.
(Example 5) The playback device of Example 4, wherein the contamination detection circuitry is configured to detect an impedance between at least one of the one or more data pins and at least one of the one or more power pins of the multi-pin connector and to output the contamination signal indicating the state of contamination of the multi-pin connector based on the impedance.
(Example 6) The playback device of Example 5, wherein the contamination detection circuitry is configured to output the contamination signal indicating that the state of contamination of the multi-pin connector is contaminated based on the impedance indicating an electrical short between the at least one data pin and the at least one power pin.
(Example 7) The playback device of Example 5, wherein the contamination detection circuitry is configured to induce a test current through the at least one data pin and through a known resistance coupled to the at least one power pin, and measure a differential voltage across the known resistance; and wherein the tangible, non-transitory computer-readable memory further includes program instructions that are executable by the one or more processors to cause the playback device to determine a magnitude of the test current based on the measured differential voltage, and to determine the impedance between the at least one data pin and the at least one power pin based on the magnitude of the test current.
(Example 8) The playback device of Example 5, wherein the input circuitry includes a first electrical connection between the at least one data pin and the at least one power pin, the first electrical connection having a known first impedance value; and wherein the contamination detection circuitry is configured to: detect a second impedance value between the at least one data pin and the at least one power pin; and output the contamination signal indicating the state of contamination of the multi-pin connector based on the second impedance value.
(Example 9) The playback device of Example 8, wherein the contamination detection circuitry includes: a test resistance coupled to the at least one data pin and to the at least one power pin; and a differential amplifier configured to measure a voltage across the test resistance; wherein the contamination detection circuitry is configured to output the contamination signal based on the measured voltage across the test resistance.
(Example 10) The playback device of Example 8, wherein the tangible, non-transitory computer-readable memory further includes program instructions that are executable by the one or more processors such that the one or more processors are configured to: detect the second impedance value; compare the second impedance value to the known first impedance value to determine an impedance change value; determine if the contamination signal comprises an indication of an impedance event based on the impedance change value; and cause the playback device to provide the alert based on a determination that the contamination signal comprises the indication of the impedance event.
(Example 11) The playback device of Example 10, wherein the indication of the impedance event comprises an indication that there is an electrical short between the at least one data pin and the at least one power pin of the multi-pin connector.
(Example 12) The playback device of Example 11, wherein the contamination detection circuitry comprises: at least one test resistor configured to measure the second impedance value; and at least one operational amplifier operably connected to the at least one test resistor and configured to output the contamination signal.
(Example 13) The playback device of any one of Examples 1-12, wherein the tangible, non-transitory computer-readable memory further includes program instructions that are executable by the one or more processors to cause the playback device to: determine if an external cable is connected to the input circuitry; and based on the external cable not being connected to the input circuitry, process the contamination signal according to a first processing schedule.
(Example 14) The playback device of Example 13, wherein the tangible, non-transitory computer-readable memory further includes program instructions that are executable by the one or more processors to cause the playback device to process the contamination signal according to a second processing schedule based on the external cable being connected to the input circuitry, wherein the second processing schedule comprises processing the contamination signal more frequently than the first processing schedule.
(Example 15) The playback device of any one of Examples 1-14, wherein the multi-pin connector is a universal serial bus (USB) type-C connector.
(Example 16) The playback device of any one of Examples 1-15, wherein the tangible, non-transitory computer-readable memory further includes program instructions that are executable by the one or more processors to cause the playback device to: receive a first audio stream via the input circuitry; and play back audio content based on the first audio stream via the audio output interface.
(Example 17) The playback device of Example 16, further comprising one or more wireless communication interfaces and wherein the tangible, non-transitory computer-readable memory further includes program instructions that are executable by the one or more processors to cause the playback device to: generate a second audio stream based on the first audio stream; and transmit the second audio stream to at least one other playback device via the one or more wireless communication interfaces.
(Example 18) The playback device of Example 17, wherein the program instructions that are executable by the one or more processors to cause the playback device to play back the second audio content comprises program instructions that are executable by the one or more processors to cause the playback device to play back the second audio content in synchrony with the at least one other playback device.
(Example 19) The playback device of any one of Examples 1-18, further comprising one or more wireless communication interfaces and wherein the program instructions that are executable by the one or more processors to cause an alert to be provided based on the contamination signal indicating that the state of contamination of the multi-pin connector is contaminated comprises program instructions that are executable by the one or more processors to cause the playback device to transmit an indication that the multi-pin connector is contaminated to at least one external device via the one or more wireless communication interfaces.
(Example 20) A playback device assembly comprising: a playback device including one or more processors, an audio output interface operably connected to the one or more processors and configured to output audio, one or more rechargeable power sources configured to provide power to the playback device, input circuitry including a multi-pin connector configured to receive both charging power and data, contamination detection circuitry operably coupled to the one or more processors and to at least a portion of the multi-pin connector, the contamination detection circuitry configured to output a contamination signal indicating a state of contamination of the multi-pin connector, and a tangible, non-transitory computer-readable memory operably connected to the one or more processors and including program instructions that are executable by the one or more processors such that the one or more processors are configured to: detect the contamination signal from the contamination detection circuitry, and cause an alert to be provided if the contamination signal indicates that the state of contamination of the multi-pin connector is contaminated; and a multi-function cable configured to be connected to the multi-pin connector.
(Example 21) The playback device assembly of Example 20, wherein the multi-pin connector is a universal serial bus (USB) type-C connector, and the multi-function cable includes a mating USB type-C connector.
(Example 22) The playback device assembly of one of Examples 20 and 21, wherein the input circuitry is configured to receive the charging power and the data via the multi-function cable.
(Example 23) The playback device assembly of one of Examples 20 and 21, wherein the multi-pin connector includes one or more data pins configured to receive and transfer at least a portion of the data to the one or more processors, and one or more power pins configured to receive and transfer at least a portion of the charging power to the one or more rechargeable power sources; and wherein the contamination detection circuitry is configured to detect an impedance value between at least one data pin of the one or more data pins and at least one power pin of the one or more power pins and to output the contamination signal indicating the impedance value.
(Example 24) The playback device assembly of Example 23, wherein the tangible, non-transitory computer-readable memory further includes program instructions are executable by the one or more processors such that the one or more processors are configured to compare the impedance value indicated by the contamination signal to a known expected impedance value to determine an impedance change value, and to cause the alert to be provided if the impedance change value indicates that the state of contamination of the multi-pin connector is contaminated.
(Example 25) The playback device assembly of any one of Examples 20-24, wherein the multi-function cable includes a resettable fuse that is configured to have an impedance that increases with temperature.
(Example 26) The playback device assembly of one of Examples 20 and 21, wherein the playback device further comprises recharging circuitry operably connected to the input circuitry and configured to: receive and condition the charging power from the input circuitry; and provide the conditioned charging power to the one or more rechargeable power sources.
(Example 26) The playback device assembly of Example 25, wherein the tangible, non-transitory computer-readable memory further includes program instructions that are executable by the one or more processors such that the one or more processors are configured to cause at least a portion of the recharging circuitry to turn off if the contamination signal indicates that the state of contamination of the multi-pin connector is contaminated.
(Example 27) The playback device assembly of Example 25, wherein the multi-pin connector comprises: one or more data pins configured to receive and transfer at least a portion of the data to the one or more processors; and one or more power pins configured to receive and transfer at least a portion of the charging power to the recharging circuitry.
(Example 28) The playback device assembly of Example 27, wherein the contamination detection circuitry is configured to detect an impedance between at least one of the one or more data pins and at least one of the one or more power pins of the multi-pin connector and to output the contamination signal indicating the state of contamination of the multi-pin connector based on the impedance.
(Example 29) The playback device assembly of Example 28, wherein the contamination detection circuitry is configured to output the contamination signal indicating that the state of contamination of the multi-pin connector is contaminated based on the impedance indicating an electrical short between the at least one data pin and the at least one power pin.
(Example 30) The playback device assembly of Example 28, wherein the contamination detection circuitry is configured to induce a test current through the at least one data pin and through a known resistance coupled to the at least one power pin, and measure a differential voltage across the known resistance; and wherein the tangible, non-transitory computer-readable memory further includes program instructions that are executable by the one or more processors to cause the playback device to determine a magnitude of the test current based on the measured differential voltage, and to determine the impedance between the at least one data pin and the at least one power pin based on the magnitude of the test current.
(Example 31) The playback device assembly of Example 28, wherein the input circuitry includes a first electrical connection between the at least one data pin and the at least one power pin, the first electrical connection having a known first impedance value; and wherein the contamination detection circuitry is configured to: detect a second impedance value between the at least one data pin and the at least one power pin; and output the contamination signal indicating the state of contamination of the multi-pin connector based on the second impedance value.
(Example 32) The playback device assembly of Example 31, wherein the contamination detection circuitry includes: a test resistance coupled to the at least one data pin and to the at least one power pin; and a differential amplifier configured to measure a voltage across the test resistance; wherein the contamination detection circuitry is configured to output the contamination signal based on the measured voltage across the test resistance.
(Example 33) The playback device assembly of Example 31, wherein the tangible, non-transitory computer-readable memory further includes program instructions that are executable by the one or more processors such that the one or more processors are configured to: detect the second impedance value; compare the second impedance value to the known first impedance value to determine an impedance change value; determine if the contamination signal comprises an indication of an impedance event based on the impedance change value; and cause the playback device to provide the alert based on a determination that the contamination signal comprises the indication of the impedance event.
(Example 34) The playback device assembly of Example 33, wherein the indication of the impedance event comprises an indication that there is an electrical short between the at least one data pin and the at least one power pin of the multi-pin connector.
(Example 35) The playback device assembly of Example 34, wherein the contamination detection circuitry comprises: at least one test resistor configured to measure the second impedance value; and at least one operational amplifier operably connected to the at least one test resistor and configured to output the contamination signal.
(Example 36) The playback device assembly of any one of Examples 20-35, wherein the tangible, non-transitory computer-readable memory further includes program instructions that are executable by the one or more processors to cause the playback device to: determine if the multi-function cable is connected to the input circuitry; and based on the multi-function cable not being connected to the input circuitry, process the contamination signal according to a first processing schedule.
(Example 37) The playback device assembly of Example 36, wherein the tangible, non-transitory computer-readable memory further includes program instructions that are executable by the one or more processors to cause the playback device to process the contamination signal according to a second processing schedule based on the multi-function cable being connected to the input circuitry, wherein the second processing schedule comprises processing the contamination signal more frequently than the first processing schedule.
(Example 38) The playback device assembly of any one of Examples 20-37, wherein the tangible, non-transitory computer-readable memory further includes program instructions that are executable by the one or more processors to cause the playback device to: receive a first audio stream via the input circuitry; and play back audio content based on the first audio stream via the audio output interface.
(Example 39) The playback device assembly of Example 38, wherein the playback device comprises one or more wireless communication interfaces and wherein the tangible, non-transitory computer-readable memory further includes program instructions that are executable by the one or more processors to cause the playback device to: generate a second audio stream based on the first audio stream; and transmit the second audio stream to at least one other playback device via the one or more wireless communication interfaces.
(Example 40) The playback device assembly of Example 39, wherein the program instructions that are executable by the one or more processors to cause the playback device to play back the second audio content comprise program instructions that are executable by the one or more processors to cause the playback device to play back the second audio content in synchrony with the at least one other playback device.
(Example 41) The playback device assembly of one of Examples 20 and 21, wherein the playback device comprises one or more wireless communication interfaces and wherein the program instructions that are executable by the one or more processors to cause an alert to be provided based on the contamination signal indicating that the state of contamination of the multi-pin connector is contaminated comprise program instructions that are executable by the one or more processors to cause the playback device to transmit an indication that the multi-pin connector is contaminated to at least one external device via the one or more wireless communication interfaces.
(Example 42) a method for a device, the method comprising detecting a contamination state of input circuitry comprising a multi-pin connector configured to receive charging power and data, based on the detected contamination state, causing at least one of: an alert, and turning off at least a portion of recharging circuitry for receiving charging power from the input circuitry.
(Example 43) The method of Example 42, wherein detecting the contamination state comprises detecting an impedance between at least one of one or more data pins and at least one of one or more power pins of the multi-pin connector.
(Example 44) The method of Example 43, wherein detecting the contamination state comprises detecting an impedance indicating an electrical short between the at least one data pin and the at least one power pin.
(Example 45) The method of one of Examples 43 or 44, wherein detecting the impedance comprises inducing a current through the at least one data pin and a known resistance coupled to the at least one power pin, measuring a differential voltage across the known resistance, and based on the measured differential voltage, determining a magnitude of the test current, and determining the impedance between the at least one data pin and the at least one power pin based on the magnitude of the test current.
(Example 46) The method of Example 43, wherein detecting the impedance comprises detecting a first impedance value between the at least one data pin and the at least one power pin, and outputting the contamination signal indicating the state of contamination when a change of impedance between the first impedance value and a known second impedance value between the at least one data pin and the at least on power pin indicates an impedance event.
(Example 47) The method of Example 42, further comprising detecting the contamination state based on a measured voltage across a test resistance coupled to the at least one data pin and the at least one power pin.
(Example 48) The method of any one of Examples 42-47, further comprising: when an external cable is not connected to the input circuitry, processing the contamination signal according to a first processing schedule, and when the external cable is connected to the input circuitry, cause the playback device to processing the contamination signal according to a second processing schedule, wherein the second processing schedule comprises processing the contamination signal more frequently than the first processing schedule.
(Example 49) The method of any one of Examples 42-48, wherein the device is a playback device, the method further comprising receiving a first audio stream via the input circuitry, and displaying back audio content based on the first audio stream via the audio output interface.
(Example 50) a playback device comprising an audio output interface operably connected to the one or more processors and configured to output audio, one or more rechargeable power sources configured to provide power to the playback device, input circuitry including a multi-pin connector configured to receive both charging power and data, and contamination detection circuitry configured to output a contamination signal indicating a state of contamination of the multi-pin connector. The playback device further comprises one or more processors are configured to at least one of: cause an alert to be provided based on the contamination signal, and cause at least a portion of recharging circuitry to turn off based on the contamination signal.
(Example 51) includes the playback device of Example 50, further comprising the recharging circuitry, and further configured to: receive and condition the charging power from the input circuitry, and provide the conditioned charging power to the one or more rechargeable power sources.
(Example 52) The playback device of one of Examples 50 or 51, wherein the multi-pin connector comprises one or more data pins configured to receive and transfer at least a portion of the data to the one or more processors, and one or more power pins configured to receive and transfer at least a portion of the charging power to the recharging circuitry.
(Example 53) The playback device of Example 52 wherein the contamination detection circuitry is configured to detect an impedance between at least one of the one or more data pins and at least one of the one or more power pins of the multi-pin connector, and wherein outputting the contamination signal indicating the state of contamination of the multi-pin connector is based on the impedance.
(Example 54) The playback device of Example 53, wherein the contamination detection circuitry is configured to output the contamination signal indicating that the state of contamination of the multi-pin connector is contaminated based on the impedance indicating an electrical short between the at least one data pin and the at least one power pin.
(Example 55) The playback device of Example 54, wherein the contamination detection circuitry is configured to induce a test current through the at least one data pin and through a known resistance coupled to the at least one power pin, and measure a differential voltage across the known resistance, and wherein the one or more processors are configured to cause the playback device to determine a magnitude of the test current based on the measured differential voltage, and to determine the impedance between the at least one data pin and the at least one power pin based on the magnitude of the test current.
(Example 56) The playback device of Example 53, wherein the input circuitry includes a first electrical connection between the at least one data pin and the at least one power pin, the first electrical connection having a known first impedance value, and wherein the contamination detection circuitry is configured to: detect a second impedance value between the at least one data pin and the at least one power pin, and output the contamination signal indicating the state of contamination of the multi-pin connector when a change of impedance between the first impedance value and the second impedance value indicates an impedance event, optionally wherein the impedance event indicates that there is an electrical short between the at least one data pin and the at least one power pin.
(Example 57) The playback device of Example 56, wherein the contamination detection circuitry includes a test resistance coupled to the at least one data pin and to the at least one power pin, and a differential amplifier configured to measure a voltage across the test resistance, and wherein the contamination detection circuitry is configured to output the contamination signal based on the measured voltage across the test resistance.
(Example 58) The playback device of Example 56, wherein the contamination detection circuitry comprises at least one test resistor configured to measure the second impedance value, and at least one operational amplifier operably connected to the at least one test resistor and configured to output the contamination signal.
(Example 59) The playback device of Example 50, wherein the one or more processors are configured to cause the playback device to: when an external cable is not connected to the input circuitry, process the contamination signal according to a first processing schedule, and when the external cable is connected to the input circuitry, process the contamination signal according to a second processing schedule, wherein the second processing schedule comprises processing the contamination signal more frequently than the first processing schedule.
(Example 60) The playback device of any one of Examples 50-59, wherein the multi-pin connector is a universal serial bus (USB) type-C connector.
(Example 61) The playback device of any one of Examples 50-60, wherein the one or more processors are configured to cause the playback device to receive a first audio stream via the input circuitry, and play back audio content based on the first audio stream via the audio output interface.
(Example 62) The playback device of Example 61, further comprising one or more wireless communication interfaces, wherein the one or more processors are configured to cause the playback device to: generate a second audio stream based on the first audio stream, transmit the second audio stream to at least one other playback device via the one or more wireless communication interfaces, and play back the second audio stream in synchrony with the at least one other playback device.
(Example 63) The playback device of any one of Examples 50-61, further comprising one or more wireless communication interfaces, and wherein causing an alert to be provided based on the contamination signal comprises causing the playback device to transmit an indication that the multi-pin connector is contaminated to at least one external device via the one or more wireless communication interfaces.
(Example 64) A playback device assembly comprising the playback device of any one of Examples 50-63, and a multi-function cable configured to be connected to the multi-pin connector.
(Example 65) The playback device assembly of Example 64, wherein the multi-pin connector is a universal serial bus (USB) type-C connector, and the multi-function cable includes a mating USB type-C connector.
(Example 66) The playback device assembly of Example 64, wherein the input circuitry is configured to receive the charging power and the data via the multi-function cable.
(Example 67) The playback device assembly of Example 64, wherein the multi-function cable includes a resettable fuse that is configured to have an impedance that increases with temperature.

1. A method for a device, the method comprising:
detecting a contamination state of input circuitry comprising a multi-pin connector configured to receive charging power and data; and
responsive to detecting the contamination state, causing at least one of:
an alert, and
turning off at least a portion of recharging circuitry for receiving charging power from the input circuitry.

2. The method of claim 1, wherein detecting the contamination state comprises:
detecting an impedance between at least one of one or more data pins of the multi-pin connector and at least one of one or more power pins of the multi-pin connector, the impedance indicating an electrical short between the at least one data pin and the at least one power pin.

3. (canceled)

4. The method of claim 2, wherein detecting the impedance comprises:
inducing a current through the at least one data pin and a known resistance coupled to the at least one power pin;
measuring a differential voltage across the known resistance;
based on the measured differential voltage, determining a magnitude of the test current; and
determining the impedance between the at least one data pin and the at least one power pin based on the magnitude of the test current.

5. The method of claim 1, wherein detecting the impedance comprises:
detecting a first impedance value between at least one data pin of the multi-pin connector and at least one power pin of the multi-pin connector, and
outputting a contamination signal indicating the contamination state when a change of impedance between the first impedance value and a known second impedance value between the at least one data pin and the at least one power pin indicates an impedance event.

6. The method of claim 1, further comprising detecting the contamination state based on a measured voltage across a test resistance coupled to at least one data pin of the multi-pin connector and at least one power pin of the multi-pin connector.

7. The method of claim 1, further comprising:
when an external cable is not connected to the input circuitry, processing the contamination signal according to a first processing schedule; and
when the external cable is connected to the input circuitry, processing the contamination signal according to a second processing schedule, wherein the second processing schedule comprises processing the contamination signal more frequently than the first processing schedule.

8. (canceled)

9. A playback device comprising:
an audio output interface operably connected to one or more processors and configured to output audio;
one or more rechargeable power sources configured to provide power to the playback device;
input circuitry including a multi-pin connector configured to receive both charging power and data;
recharging circuitry configured to receive and condition the charging power from the input circuitry and to provide the conditioned charging power to the one or more rechargeable power sources;
contamination detection circuitry configured to output a contamination signal indicating a state of contamination of the multi-pin connector; and
the one or more processors, wherein the one or more processors are configured to at least one of:
cause an alert to be provided based on the contamination signal, and
cause at least a portion of the recharging circuitry to turn off based on the contamination signal.

10. (canceled)

11. The playback device of claim 9, wherein:
the multi-pin connector comprises:
one or more data pins configured to receive and transfer at least a portion of the data to the one or more processors, and
one or more power pins configured to receive and transfer at least a portion of the charging power to the recharging circuitry;
the contamination detection circuitry is configured to detect an impedance between at least one of the one or more data pins and at least one of the one or more power pins of the multi-pin connector; and
the contamination detection circuitry is configured to output the contamination signal indicating the state of contamination of the multi-pin connector based on the impedance.

12. (canceled)

13. The playback device of claim 11, wherein the contamination detection circuitry is configured to output the contamination signal indicating that the state of contamination of the multi-pin connector is contaminated based on the impedance indicating an electrical short between the at least one data pin and the at least one power pin.

14. The playback device of claim 13, wherein:
the contamination detection circuitry is configured to induce a test current through the at least one data pin and through a known resistance coupled to the at least one power pin, and measure a differential voltage across the known resistance; and
wherein the one or more processors are configured to:
cause the playback device to determine a magnitude of the test current based on the measured differential voltage, and
determine the impedance between the at least one data pin and the at least one power pin based on the magnitude of the test current.

15. The playback device of claim 11, wherein the input circuitry includes a first electrical connection between the at least one data pin and the at least one power pin, the first electrical connection having a known first impedance value; and
wherein the contamination detection circuitry is configured to:
detect a second impedance value between the at least one data pin and the at least one power pin, and
output the contamination signal indicating the state of contamination of the multi-pin connector when a change of impedance between the first impedance value and the second impedance value indicates an impedance event, optionally wherein the impedance event indicates that there is an electrical short between the at least one data pin and the at least one power pin.

16. The playback device of claim 15, wherein the contamination detection circuitry includes:
a test resistance coupled to the at least one data pin and to the at least one power pin; and
a differential amplifier configured to measure a voltage across the test resistance;
wherein the contamination detection circuitry is configured to output the contamination signal based on the measured voltage across the test resistance.

17. The playback device of claim 15, wherein the contamination detection circuitry comprises:
at least one test resistor configured to measure the second impedance value; and
at least one operational amplifier operably connected to the at least one test resistor and configured to output the contamination signal.

18. The playback device of claim 9, wherein the one or more processors are configured to cause the playback device to:
when an external cable is not connected to the input circuitry, process the contamination signal according to a first processing schedule; and
when the external cable is connected to the input circuitry, process the contamination signal according to a second processing schedule, wherein the second processing schedule comprises processing the contamination signal more frequently than the first processing schedule.

19. The playback device of claim 9, wherein the multi-pin connector is a universal serial bus (USB) type-C connector.

20. The playback device of claim 9, wherein the one or more processors are configured to cause the playback device to:
receive a first audio stream via the input circuitry;
generate a second audio stream based on the first audio stream;
transmit the second audio stream to at least one other playback device via the one or more wireless communication interfaces; and
play back, via the audio output interface, audio content derived from the first audio stream in synchrony with the at least one other playback device.

21. (canceled)

22. The playback device of claim 2, further comprising one or more wireless communication interfaces, and wherein causing an alert to be provided based on the contamination signal comprises causing the playback device to transmit an indication that the multi-pin connector is contaminated to at least one external device via the one or more wireless communication interfaces.

23. A playback device assembly comprising:
a playback device comprising
one or more processors,
an audio output interface operably connected to one or more processors and configured to output audio,
one or more rechargeable power sources configured to provide power to the playback device,
input circuitry including a multi-pin connector configured to receive both charging power and data,
recharging circuitry configured to receive and condition the charging power from the input circuitry and to provide the conditioned charging power to the one or more rechargeable power sources, and
contamination detection circuitry configured to output a contamination signal indicating a state of contamination of the multi-pin connector,
wherein the one or more processors are configured to at least one of:
cause an alert to be provided based on the contamination signal, and
cause at least a portion of the recharging circuitry to turn off based on the contamination signal; and
a multi-function cable configured to be connected to the multi-pin connector;
wherein the input circuitry is configured to receive the charging power and the data via the multi-function cable.

24. The playback device assembly of claim 23, wherein the multi-pin connector is a universal serial bus (USB) type-C connector and the multi-function cable includes a mating USB type-C connector.

25. (canceled)

26. The playback device assembly of claim 23, wherein the multi-function cable includes a resettable fuse that is configured to have an impedance that increases with temperature.
